(19) United States
(12) Patent Application Publication
(10) Pub. No.: US 2023/0215942 A1
(43) Pub. Date: Jul. 6, 2023

(54) SEMICONDUCTOR DEVICE, POWER CONVERSION APPARATUS, AND METHOD FOR PRODUCING SEMICONDUCTOR DEVICE

(71) Applicant: Mitsubishi Electric Corporation, Tokyo (JP)

(72) Inventors: Rina TANAKA, Tokyo (JP); Hideyuki HATTA, Tokyo (JP); Motoru YOSHIDA, Tokyo (JP); Yutaka FUKUI, Tokyo (JP); Shiro HINO, Tokyo (JP)

(73) Assignee: Mitsubishi Electric Corporation, Tokyo (JP)

(21) Appl. No.: 18/008,673

(22) PCT Filed: Aug. 25, 2020
(86) PCT No.: PCT/JP2020/031924

§ 371 Date: Dec. 7, 2022

(51) Int. Cl. H01L 29/78; H01L 29/66

(52) U.S. Cl. CPC H01L 29/7806; H01L 29/7813; H01L 29/66734; H01L 29/66143

(57) ABSTRACT

A semiconductor device according to the present disclosure includes: a gate electrode provided in a gate trench and provided so as to oppose a source region via a gate insulating film; a first bottom protection region of a second conductivity type provided below the gate insulating film; a plurality of first connection regions of the second conductivity type provided at a first interval in an extension direction of the gate trench and electrically connecting the first bottom protection region and a body region; a Schottky electrode provided in a Schottky trench; a second bottom protection region of the second conductivity type provided below the Schottky electrode; and a plurality of second connection regions of the second conductivity type provided at a second interval smaller than the first interval in an extension direction of the Schottky trench and electrically connecting the second bottom protection region and the body region.

### TECHNICAL FIELD

The present disclosure relates to a semiconductor device, a power conversion apparatus, and a method for producing a semiconductor device.

### BACKGROUND ART

As a conventional semiconductor device, there is a trench type SiC metal-oxide-semiconductor field-effect-transistor (SiC-MOSFET) including a gate trench and a contact trench on a front surface side of a semiconductor substrate (semiconductor chip). The gate trench is a trench in which a gate electrode is embedded via a gate insulating film. The contact trench is a trench in which a Schottky barrier diode (SBD) having a Schottky junction by a Schottky electrode is embedded.

In this conventional semiconductor device, the gate trench and the contact trench reach an n-type high-concentration region through a p-type base layer from the surface of the p-type base layer opposite to an n⁺-type silicon carbide substrate side (first main surface side of the silicon carbide semiconductor substrate). The gate trench is arranged in a parallel striped planar layout extending in a depth direction (X-X′ direction). The contact trench is arranged in a striped planar layout extending in the X-X′ direction between adjacent gate trenches in parallel with the gate trench and separated from the gate trench.

In a vertical MOSFET having the trench structure as described above, a channel is formed perpendicular to the substrate surface, therefore the cell density per unit area can be increased as compared with the planar structure in which the channel is formed parallel to the substrate surface, and the current density per unit area can be increased, which are advantageous in terms of cost. When elements having the same on-resistance (Ron) are compared with each other, the trench gate structure can have a smaller element area (chip area) than that of a planar gate structure in which a MOS gate is provided in a flat plate shape on a silicon carbide substrate.

On the other hand, in a structure having a built-in SBD as described above, a drift region can be shared by a built-in SBD and the MOSFET, and thus the chip area can be smaller than the total chip area of an external SBD and the MOSFET. In the structure having a built-in SBD, even when the voltage at the drain of the MOSFET becomes equal to or greater than the built-in voltage of a body diode formed by the p-type base layer and an n⁻-type drift layer, the potential difference near pn junction constituting the body diode is low because the voltage is held in the drift region, and the current hardly flows through the body diode. Therefore, unlike the case of the external SBD, the current does not flow through the body diode up to a large current, and it is possible to suppress characteristics from changing over time (aged deterioration) due to bipolar operation of the body diode and reliability from reducing.

In the above-described conventional semiconductor device, a p⁺-type base region is further provided selectively on a surface layer of the n⁻-type drift layer on an opposite side (first main surface side of silicon carbide semiconductor substrate) to the n⁺-type silicon carbide substrate side. The p⁺-type base region is formed below the gate trench and the contact trench, and the width of the p⁺-type base region is wider than the widths of the gate trench and the contact trench. The p⁺-type base region is provided apart from the p-type base layer. The p⁺-type base region is provided to relax the electric field applied to the gate insulating film at the bottom of the gate trench and the contact trench.

The n-type high-concentration region is a high-concentration n-type drift layer doped with nitrogen, for example, at an impurity concentration lower than that of the n⁺-type silicon carbide substrate and higher than that of the n⁻-type drift layer. The n-type high-concentration region is a so-called current spreading layer (CSL) that reduces carrier spreading resistance (for example, Patent Document 1).

### PRIOR ART DOCUMENT

### Patent Document

Patent Document 1: Japanese Patent Application Laid-Open No. 2019-216224 (Paragraphs 0002 to 0010 and 0027 to 0034 and FIGS. 1 and 3)

### SUMMARY

### Problem to be Solved by the Invention

In a trench type semiconductor device having a built-in SBD, a trench side surface exposed to an n-type semiconductor region is likely to have a high electric field, and at the time of applying the reverse bias, leakage current from a Schottky interface formed in the portion increases, and a withstand voltage at an element may be deteriorated. For this problem, by reducing the concentration of the n-type semiconductor region around the region where the SBD is formed, it is possible to suppress an increase in the leakage current of the SBD at the time of applying the reverse bias. However, in the semiconductor device described in Patent Document 1, the surrounding impurity layers are similarly configured by the region where the gate trench is formed and the region where the contact trench is formed, and therefore when the concentration of the n-type high-concentration region is reduced to suppress the increase in the leakage current, the on-resistance of the MOSFET increases. That is, it is difficult to improve trade-off between the characteristics of the MOSFET and the SBD.

The present disclosure has been made to solve the above-described problems, and an object is to provide a semiconductor device of a trench type having a built-in SBD, the semiconductor device being capable of suppressing a leakage current increase of an SBD while reducing on-resistance of an element.

### Means to Solve the Problem

A semiconductor device according to the present disclosure includes: a drift layer of a first conductivity type; a body region of a second conductivity type; a source region of a first conductivity type; a gate insulating film provided in a gate trench penetrating the body region in a thickness direction of the drift layer; a gate electrode provided in the gate trench and provided to oppose the source region via the gate insulating film; a first bottom protection region of a second conductivity type provided below the gate insulating film; a plurality of first connection regions of a second conductivity type provided at a first interval in an extension direction of the gate trench and electrically connecting the first bottom protection region and the body region; a Schottky electrode provided in a Schottky trench penetrating the body region in the thickness direction of the drift layer, the Schottky electrode having a Schottky interface formed on a side surface of the Schottky trench; a second bottom protection region of a second conductivity type provided below the Schottky electrode; and a plurality of second connection regions of a second conductivity type provided at a second interval smaller than the first interval in an extension direction of the Schottky trench and electrically connecting the second bottom protection region and the body region.

A method for producing a semiconductor device according to the present disclosure includes: a step of forming a body region of a second conductivity type in an upper layer portion of a drift layer of a first conductivity type; a step of selectively forming a source region of a first conductivity type in an upper layer portion of the body region; a step of forming a gate trench penetrating the source region and the body region and reaching the drift layer; a step of forming a Schottky trench penetrating the body region and reaching the drift layer; a step of forming a first bottom protection region of a second conductivity type below the gate trench; a step of forming a second bottom protection region of a second conductivity type below the Schottky trench; a step of forming a plurality of first connection regions of a second conductivity type so as to connect the body region and the first bottom protection region by performing ion implantation in an oblique direction with respect to a side surface of the gate trench using a mask periodically opened at a first interval in an extension direction of the gate trench; a step of forming a plurality of second connection regions of a second conductivity type so as to connect the body region and the second bottom protection region by performing ion implantation in an oblique direction with respect to a side surface of the Schottky trench using a mask periodically opened at a second interval smaller than the first interval in an extension direction of the Schottky trench; a step of forming a gate insulating film on a bottom and a side surface of the gate trench; a step of forming a gate electrode so as to embed the gate trench via the gate insulating film; and a step of forming a Schottky electrode in the Schottky trench.

A method for producing a semiconductor device according to the present disclosure includes: a step of selectively forming, by ion implantation, a first bottom protection region of a second conductivity type and a second bottom protection region of a second conductivity type in an upper layer portion of a first drift layer of a first conductivity type; a step of forming, by epitaxial growth, a second drift layer of a first conductivity type on the first drift layer, the first bottom protection region, and the second bottom protection region; a step of forming a body region of a second conductivity type in an upper layer portion of the second drift layer; a step of selectively forming a source region of a first conductivity type in an upper layer portion of the body region; a step of forming a gate trench penetrating the source region and the body region and reaching the first bottom protection region; a step of forming a Schottky trench penetrating the body region and reaching the second bottom protection region; a step of forming a plurality of first connection regions of a second conductivity type so as to connect the body region and the first bottom protection region by performing ion implantation in an oblique direction with respect to a side surface of the gate trench using a mask periodically opened at a first interval in an extension direction of the gate trench; a step of forming a plurality of second connection regions of a second conductivity type so as to connect the body region and the second bottom protection region by performing ion implantation in an oblique direction with respect to a side surface of the Schottky trench using a mask periodically opened at a second interval smaller than the first interval in an extension direction of the Schottky trench; a step of forming a gate insulating film on a bottom and the side surface of the gate trench; a step of forming a gate electrode so as to embed the gate trench via the gate insulating film; and a step of forming a Schottky electrode in the Schottky trench.

### Effects of the Invention

Since the semiconductor device according to the present disclosure includes: the plurality of first connection regions of a second conductivity type provided at the first interval in the extension direction of the gate trench and electrically connecting the first bottom protection region and the body region; and the plurality of second connection regions of a second conductivity type provided at the second interval smaller than the first interval in the extension direction of the Schottky trench and electrically connecting the second bottom protection region and the body region, the semiconductor device can suppress a leakage current increase of an SBD while reducing on-resistance of an element.

### BRIEF DESCRIPTION OF DRAWINGS

FIG. 1 is a schematic cross sectional view of a cell region in a semiconductor device of a first embodiment.

FIG. 2 is a schematic plan view showing a layout in the semiconductor device of the first embodiment.

FIG. 3 is a view showing a process of producing the semiconductor device in the first embodiment.

FIG. 4 is a view showing a process of producing the semiconductor device in the first embodiment.

FIG. 5 is a view showing a process of producing the semiconductor device in the first embodiment.

FIG. 6 is a view showing a process of producing the semiconductor device in the first embodiment.

FIG. 7 is a view showing a process of producing the semiconductor device in the first embodiment.

FIG. 8 is a view showing a process of producing the semiconductor device in the first embodiment.

FIG. 9 is a view showing a process of producing the semiconductor device in the first embodiment.

FIG. 10 is a schematic plan view showing a layout in a semiconductor device of a first modification of the first embodiment.

FIG. 11 is a schematic cross sectional view of a cell region in a semiconductor device of a second modification of the first embodiment.

FIG. 12 is a schematic cross sectional view of a cell region in a semiconductor device of a second embodiment.

FIG. 13 is a view showing a process of producing the semiconductor device in the second embodiment.

FIG. 14 is a schematic cross sectional view of a cell region in a semiconductor device of a first modification of the second embodiment.

FIG. 15 is a view showing a process of producing the semiconductor device in the first modification of the second embodiment.

FIG. 16 is a view showing a process of producing the semiconductor device in the first modification of the second embodiment.

FIG. 17 is a view showing a process of producing the semiconductor device in the first modification of the second embodiment.

FIG. 18 is a schematic cross sectional view of a cell region in a semiconductor device of a second modification of the second embodiment.

FIG. 19 is a view showing a process of producing the semiconductor device in the second modification of the second embodiment.

FIG. 20 is a view showing a process of producing the semiconductor device in the second modification of the second embodiment.

FIG. 21 is a schematic cross sectional view of a cell region in a semiconductor device of a third embodiment.

FIG. 22 is a schematic plan view showing a layout in the semiconductor device of the third embodiment.

FIG. 23 is a view showing a process of producing the semiconductor device in the third embodiment.

FIG. 24 is a view showing a process of producing the semiconductor device in the third embodiment.

FIG. 25 is a view showing a process of producing a semiconductor device in a first modification of the third embodiment.

FIG. 26 is a view showing a process of producing the semiconductor device in the first modification of the third embodiment.

FIG. 27 is a schematic cross sectional view of a cell region in a semiconductor device of a second modification of the third embodiment.

FIG. 28 is a block diagram showing a power conversion system applied with a power conversion apparatus according to a fourth embodiment.

### DESCRIPTION OF EMBODIMENTS

Hereinafter, embodiments of the present disclosure will be described with reference to the accompanying drawings. The drawings are schematically shown, and the mutual relationship in size and position among images shown in different drawings is not necessarily accurately described and can be changed as appropriate. In the following description, similar constituent elements are illustrated with the same reference signs given, and their names and functions are identical or similar. Therefore, there is a case where a detailed description of them is omitted.

In each drawing, a broken line is sometimes illustrated to indicate a specific region and a boundary between each region, but these are described for convenience of description or for facilitating understanding of the drawings, and do not limit the content of each of the embodiments at all.

In the following description, terms meaning specific positions and directions such as “up”, “down”, “side”, “bottom”, “front”, and “back” may be used, but these terms are used for convenience to facilitate understanding of the content of the embodiments and are not related to directions when actually carried out.

In the present disclosure, when the mutual relationship among constituent elements is expressed using terms such as “up/on/above/over” and “down/beneath/below/under”, presence of an inclusion between constituent elements is not precluded. For example, description of “B provided on A” includes what is provided with another constituent element C between A and B and what is not provided with another constituent element C between A and B. In the present disclosure, expressions using terms such as “up/on/above/over” and “down/beneath/below/under” include a concept of up/down with a lamination structure in mind. For example, description “B provided on A covering a groove” includes a meaning in which B exists in an opposite direction to a groove surface as viewed from A, and also includes a lateral direction and an oblique direction within a scope of the meaning.

In the following description, regarding the conductivity type of impurities, a case where the first conductivity type is n-type and the second conductivity type is p-type will be described, but the first conductivity type may be p-type and the second conductivity type may be n-type. The “impurity concentration” shall indicate the maximum value of an impurity in each region.

In the following description, current flowing from the drain to the source of a MOSFET is referred to as forward current, its direction is referred to as forward direction, current flowing from the source to the drain is referred to as return current, and its direction is referred to as reverse direction or the like. The term “MOS” was used in a junction structure of metal/oxide/semiconductor in the past, and is an acronym for metal-oxide-semiconductor. However, in a field-effect transistor (hereinafter, simply referred to as “MOS transistor”) having a MOS structure in particular, materials of a gate insulating film and a gate electrode have been improved from the viewpoint of recent integration, improvement of a producing process, and the like.

For example, in a MOS transistor, polycrystalline silicon has been adopted instead of metal as a material of a gate electrode from the viewpoint of forming mainly a source and a drain in a self-aligned manner. From the viewpoint of improving electrical characteristics, a material having a high permittivity is adopted as a material of the gate insulating film, but this material is not necessarily limited to an oxide.

Therefore, the term “MOS” is not necessarily adopted with a limitation only on the lamination structure of metal/oxide/semiconductor, and such limitation is not assumed in the present description. That is, in view of the common general technical knowledge, here, “MOS” has significance not only as an abbreviation derived from its etymology but also broadly including a lamination structure of conductor/insulator/semiconductor.

### First Embodiment

<Configuration>

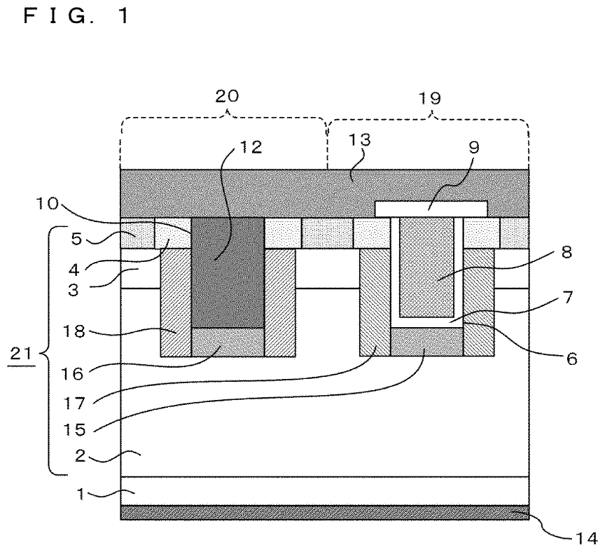

FIG. 1 is a schematic cross sectional view showing a cross section of a part of a cell region in a semiconductor device 101 according to the first embodiment of the present disclosure. In the semiconductor device 101, a plurality of cell structures as shown in FIG. 1 are repeatedly and periodically provided in a cell region.

As shown in FIG. 1, the semiconductor device 101 includes a substrate 1, a drift layer 2, a body region 3, a source region 4, a body contact region 5, a gate trench 6, a gate insulating film 7, a gate electrode 8, an interlayer insulating film 9, a Schottky trench 10, a Schottky electrode 12, a source electrode 13, a drain electrode 14, a first bottom protection region 15, a second bottom protection region 16, a first connection region 17, and a second connection region 18.

A MOS region 19 includes the gate trench 6, the gate insulating film 7, the gate electrode 8, and the interlayer insulating film 9. An SBD region 20 includes the Schottky trench 10 and the Schottky electrode 12. A semiconductor layer 21 includes the drift layer 2, and the body region 3, the source region 4, the body contact region 5, the first bottom protection region 15, the second bottom protection region 16, the first connection region 17, and second connection region 18, which are impurity regions formed on an upper portion of or inside the drift layer 2.

The substrate 1 is an n-type silicon carbide (SiC) semiconductor substrate, and has, for example, a 4H polytype. The substrate 1 may be a (0001) face having an off angle θ inclined in an <11-20> axis direction. In this case, the off angle θ is preferably equal to or less than 10°, for example.

The n-type drift layer 2 having an n-type impurity concentration lower than that of the substrate 1 is provided on the substrate 1. The drift layer 2 is made of silicon carbide (SiC) as a semiconductor material. The drift layer 2 occupies most of the semiconductor layer 21 and constitutes a main part of the semiconductor layer 21. When the main surface of the substrate 1 is the (0001) face having the off angle θ inclined in the <11-20> axis direction, the main surface of the drift layer 2 is also the (0001) face having the similar off angle θ. That is, the drift layer 2 has a main surface provided with an off angle larger than 0° in the <11-20> axis direction.

The p-type body region 3 is provided in an upper layer portion of the drift layer 2. The n-type source region 4 is selectively provided in the upper layer portion of the drift layer 2 (body region 3). The source region 4 is a semiconductor region having an n-type impurity concentration higher than that of the drift layer 2. The upper layer portion of the drift layer 2 (body region 3) is selectively provided with the p-type body contact region 5 adjacent to the source region 4. The body contact region 5 is a semiconductor region having a p-type impurity concentration higher than that of the body region 3.

The MOS region 19 is provided with the gate trench 6 penetrating the body region 3 in a thickness direction of the drift layer 2. The gate trench 6 is formed so as to penetrate the source region 4 and the body region 3 from the surface of the semiconductor layer 21 and reaches the drift layer 2. The bottom of the gate trench 6 typically forms a surface, but may have a tapered shape with a narrow and pointed tip. The side surfaces of the gate trench 6 are typically substantially parallel, but may have a tapered shape inclined with respect to each other.

The bottom and the side surfaces of the gate trench 6 are provided with the gate insulating film 7. In the gate trench 6, the gate electrode 8 is provided so as to fill the inside of the gate trench 6 via the gate insulating film 7. The gate electrode 8 is provided so as to oppose the drift layer 2, the body region 3, and the source region 4 via the gate insulating film 7. On the gate trench 6, the interlayer insulating film 9 is provided so as to cover the gate electrode 8.

The SBD region 20 is provided with the Schottky trench 10 penetrating the body region 3 in the thickness direction of the drift layer 2. The Schottky trench 10 is formed so as to penetrate the source region 4 and the body region 3 from the surface of the semiconductor layer 21 and reaches the drift layer 2. The Schottky trench 10 is formed such that the depth in the thickness direction of the drift layer 2 becomes equal to the depth of the gate trench 6. The Schottky trench 10 is formed such that the trench width in a direction orthogonal to the thickness direction of the drift layer 2 becomes equal to the width of the gate trench 6. The bottom of the Schottky trench 10 typically forms a surface, but may have a tapered shape with a narrow and pointed tip. The side surfaces of the Schottky trench 10 are typically substantially parallel, but may have a tapered shape inclined with respect to each other.

The Schottky trench 10 is not limited to that formed such that the depth in the thickness direction of the drift layer 2 becomes equal to the depth of the gate trench 6. The Schottky trench 10 is not limited to that formed such that the trench width in the direction orthogonal to the thickness direction of the drift layer 2 becomes equal to the width of the gate trench 6. The gate trench 6 and the Schottky trench 10 may have different depths in the thickness direction of the drift layer 2, or may have different trench widths in the direction orthogonal to the thickness direction of the drift layer 2. In these trenches, the trench width of either one may be large or small, the depth of either one may be large or small, and are different depending on the specifications of each semiconductor device.

The Schottky electrode 12 is provided in the Schottky trench 10. The Schottky electrode 12 is formed of a metal such as titanium (Ti) or molybdenum (Mo). The Schottky electrode 12 is in contact with and electrically connected to the drift layer 2, the body region 3, and the source region 4 at the bottom or the side surface of the Schottky trench 10.

The Schottky electrode 12 forms a Schottky junction with the drift layer 2 on the side surface of the Schottky trench 10. That is, the Schottky electrode 12 forms a Schottky interface 22 with the drift layer 2 on the side surface of the Schottky trench 10. Due to this, a parasitic Schottky barrier diode (hereinafter, simply referred to as SBD) between the Schottky electrode 12 and the drift layer 2 is formed on the side surface of the Schottky trench 10.

In the MOS region 19, an ohmic electrode not illustrated is formed on the source region 4 and the body contact region 5. The ohmic electrode is a silicide of a metal such as nickel (Ni) or titanium (Ti) and the semiconductor layer 21, and is in contact with the source region 4 and the body contact region 5 to form an ohmic contact with them.

On the interlayer insulating film 9, the ohmic electrode, and the Schottky electrode 12, the source electrode 13 is provided so as to cover them. The source electrode 13 is an electrode made of metal whose main component is aluminum (Al). In the MOS region 19, the source electrode 13 functions as a main electrode on the front surface side together with the ohmic electrode. The source electrode 13 is electrically connected to the source region 4 and the body contact region 5 via the ohmic electrode. In the SBD region 20, the source electrode 13 is connected to the Schottky electrode 12, and constitutes an anode electrode of the SBD together with the Schottky electrode 12.

In the substrate 1, a surface opposite to the surface provided with the source electrode 13 is provided with the drain electrode 14 made of nickel (Ni) metal. The source electrode 13 is provided on the front surface (first main surface) side of the substrate 1 (semiconductor layer 21), and the drain electrode 14 is provided on the back surface (second main surface) side opposing the front surface of the substrate 1 (semiconductor layer 21).

The p-type first bottom protection region 15 is provided below the gate trench 6 (gate insulating film 7) along the extension direction of the gate trench 6. The first bottom protection region 15 is in contact with the bottom of the gate trench 6 and is provided so as to cover the entire bottom of the gate trench 6. The p-type second bottom protection region 16 is provided below the Schottky trench 10 (Schottky electrode 12) along the extension direction of the Schottky trench 10. The second bottom protection region 16 is in contact with the bottom of the Schottky trench 10 and is provided so as to cover the entire bottom of the Schottky trench 10.

The p-type first connection region 17 is provided on the side of the gate trench 6. The first connection region 17 is in contact with one side surface of the gate trench 6 and is provided in contact with the body region 3 and the first bottom protection region 15. As described later, a plurality of the first connection regions 17 are provided at a first interval in the extension direction of the gate trench 6, and electrically connects the first bottom protection region 15 and the body region 3. The depth of the first connection region 17 from the outermost layer of the drift layer 2 is provided to the depth equal to that of the bottom surface of the first bottom protection region 15.

The p-type second connection region 18 is provided on the side of the Schottky trench 10. The second connection region 18 is in contact with one side surface of the Schottky trench 10 and is provided in contact with the body region 3 and the second bottom protection region 16. As described later, a plurality of the second connection regions 18 are provided at a second interval smaller than the first interval in the extension direction of the Schottky trench 10, and electrically connect the second bottom protection region 16 and the body region 3. The depth of the second connection region 18 from the outermost layer of the drift layer 2 is provided to the depth equal to that of the bottom surface of the second bottom protection region 16.

The first bottom protection region 15 is not limited to that provided in contact with the bottom of the gate trench 6, and may be provided below away from the bottom of the gate trench 6 in the drift layer 2. Similarly, the second bottom protection region 16 is also not limited to that provided in contact with the bottom of the Schottky trench 10, and may be provided below away from the bottom of the Schottky trench 10 in the drift layer 2.

The first bottom protection region 15 is not limited to that covers the entire bottom of the gate trench 6, and only needs to be provided so as to cover at least a part of the bottom of the gate trench 6. For example, the first bottom protection region 15 may be periodically arranged at an interval along the extension direction (the long direction in plan view is defined in the case of a stripe shape, and the direction is defined for each gate trench 6 in the case of a lattice shape) of the gate trench 6, or may be provided so as to cover about half of the bottom of the gate trench 6 in a cross section orthogonal to the extension direction. Alternatively, the first bottom protection region 15 may be configured such that the width of the first bottom protection region 15 becomes larger than the width of the gate trench 6 by covering the entire bottom so as to protrude in the width direction of the gate trench 6.

Similarly, the second bottom protection region 16 is not limited to that covers the entire bottom of the Schottky trench 10, and only needs to be provided so as to cover at least a part of the bottom of the Schottky trench 10. For example, the second bottom protection region 16 may be periodically arranged at an interval along the extension direction (the long direction in plan view is defined in the case of a stripe shape, and the direction is defined for each Schottky trench 10 in the case of a lattice shape) of the Schottky trench 10, or may be provided so as to cover about half of the bottom of the Schottky trench 10 in a cross section orthogonal to the extension direction. Alternatively, the second bottom protection region 16 may be configured such that the width of the second bottom protection region 16 becomes larger than the width of the Schottky trench 10 by covering the entire bottom so as to protrude in the width direction of the Schottky trench 10.

The first bottom protection region 15 is not limited to that provided along the extension direction of the gate trench 6, and a plurality of the first bottom protection regions 15 may be provided extending in the direction orthogonal to the extension direction of the gate trench 6 to partially periodically cover the bottom of the gate trench 6 in the extension direction. Similarly, the second bottom protection region 16 is not limited to that provided along the extension direction of the Schottky trench 10, and a plurality of the second bottom protection regions 16 may be provided extending in the direction orthogonal to the extension direction of the Schottky trench 10 to partially periodically cover the bottom of the Schottky trench 10 in the extension direction.

The first connection region 17 is not limited to that provided in contact with one side surface of the gate trench 6, and may be provided at a position away from the side surface of the gate trench 6 in the drift layer 2. Similarly, the second connection region 18 is also not limited to that provided in contact with one side surface of the Schottky trench 10, and may be provided at a position away from the side surface of the Schottky trench 10 in the drift layer 2.

The depth of the first connection region 17 from the outermost layer of the drift layer 2 is not limited to the depth equal to that of the bottom surface of the first bottom protection region 15, and the first connection region 17 may be provided so as to be in contact with the body region 3 and the first bottom protection region 15 to electrically connect them. For example, the first connection region 17 may be provided such that the depth from the outermost layer of the drift layer 2 becomes deeper than the bottom of the gate trench 6 and shallower than the bottom surface of the first bottom protection region 15, or may be provided up to the vicinity of the upper surface of the first bottom protection region 15.

Similarly, the depth of the second connection region 18 from the outermost layer of the drift layer 2 is not limited to the depth equal to that of the bottom surface of the second bottom protection region 16, and the second connection region 18 may be provided so as to be in contact with the body region 3 and the second bottom protection region 16 to electrically connect them. For example, the second connection region 18 may be provided such that the depth from the outermost layer of the drift layer 2 becomes deeper than the bottom of the Schottky trench 10 and shallower than the bottom surface of the second bottom protection region 16, or may be provided up to the vicinity of the upper surface of the second bottom protection region 16.

Next, the impurity concentration of each semiconductor region in the semiconductor device 101 according to the first embodiment will be described. The n-type impurity concentration of the drift layer 2 is 1.0×10¹⁴ to 1.0×10¹⁷ cm⁻³, and is set based on a withstand voltage of the semiconductor device or the like. The p-type impurity concentration of the body region 3 is set to 1.0×10¹⁴ to 1.0×10¹⁸ cm⁻³. The n-type impurity concentration of the source region 4 is set to 1.0×10¹⁸ to 1.0×10²¹ cm⁻³. The p-type impurity concentration of the body contact region 5 is set to 1.0×10¹⁸ to 1.0×10²¹ cm⁻³, and is set such that the p-type impurity concentration becomes higher than that of the body region 3 in order to reduce the contact resistance with the source electrode 13. The p-type impurity concentration of the first bottom protection region 15, the second bottom protection region 16, the first connection region 17, and the second connection region 18 is preferably equal to or greater than 1.0×10¹⁴ and equal to or less than 1.0×10²⁰ cm⁻³, and the concentration profile needs not be uniform.

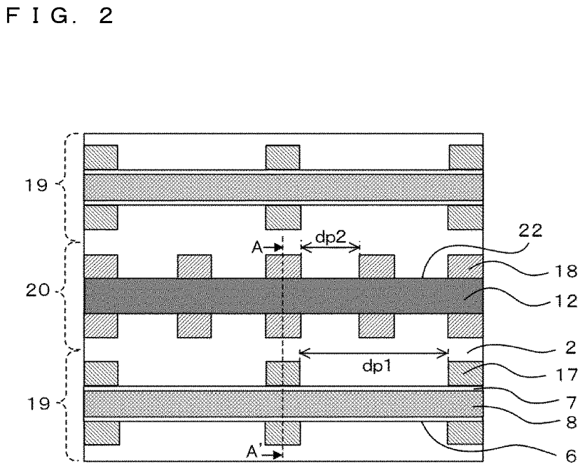

FIG. 2 is a schematic plan view schematically showing the layout of each semiconductor region in the semiconductor device 101. An A-A′ cross section of FIG. 2 corresponds to FIG. 1. FIG. 2 corresponds to a view of a cross section in a lateral direction at a certain depth between the body region 3 and the first bottom protection region 15 shown in FIG. 1 as viewed from above. As shown in FIG. 2, the gate trench 6 and the Schottky trench 10 are formed in a stripe shape in plan view. In plan view, the extension direction of the gate trench 6 and the extension direction of the Schottky trench 10 are formed to be the same direction.

The gate trench 6 and the Schottky trench 10 are desirably formed such that their extension directions become parallel to the <11-20> axis direction. This is because, since the side surfaces of the gate trench 6 and the Schottky trench 10 become a current path, in a case where the semiconductor layer 21 has the off angle θ inclined in the <11-20> axis direction, both side surfaces of each trench facing each other become different crystal planes due to the influence of the off angle, and a difference in characteristics is avoided from occurring on both side surfaces.

FIG. 2 shows a structure in which two MOS regions 19 sandwich one SBD region 20, but the arrangement of each region is not limited to this. For example, a structure in which two MOS regions 19 sandwich two or three or more SBD regions 20 may be adopted, or a structure in which arrangement such as two gate trenches 6 in the MOS region 19, three Schottky trenches 10 in the SBD region 20, two gate trenches 6 in the MOS region 19, and three Schottky trenches 10 in the SBD region 20 is repeated may be adopted, and the present invention is not limited to these examples at all.

As shown in FIG. 2, in the MOS region 19, the plurality of first connection regions 17 are periodically formed at a first interval dp1 in the extension direction of the gate trench 6. In the first embodiment, the first connection regions 17 are provided on both side surfaces of the gate trench 6.

In the SBD region 20, the plurality of second connection regions 18 are periodically formed at a second interval dp2 smaller than the first interval dp1 in the extension direction of the Schottky trench 10. In the first embodiment, the second connection regions 18 are provided on both side surfaces of the Schottky trench 10. In the SBD region 20, the above-described Schottky interface 22 is formed on the side surface of the Schottky trench 10 exposed to the drift layer 2 between the second connection regions 18.

The first connection regions 17 may be provided at different intervals from each other on both side surfaces facing each other of the gate trench 6. The first connection regions 17 need not be provided at a regular interval in the extension direction of the gate trench 6. Thus, when the arrangement intervals are different on both side surfaces of the gate trench 6 or in the extension direction of the gate trench 6, the smallest interval is set as the first interval dp1.

The first connection region 17 may be formed only on one of both side surfaces facing each other of the gate trench 6. Furthermore, in the gate trench 6, one of both side surfaces facing each other may be entirely covered with a p-type semiconductor region similar to the first connection region 17, and on the other side surface, the first connection region 17 may be periodically formed at the first interval dp1.

The second connection regions 18 may also be provided at different intervals from each other on both side surfaces facing each other of the Schottky trench 10. The second connection regions 18 need not be provided at a regular interval in the extension direction of the Schottky trench 10. Thus, when the arrangement intervals are different on both side surfaces of the Schottky trench 10 or in the extension direction of the Schottky trench 10, the smallest interval is set as the second interval dp2.

The second connection region 18 may be formed only on one of both side surfaces facing each other of the Schottky trench 10. Furthermore, in the Schottky trench 10, one of both side surfaces facing each other may be entirely covered with a p-type semiconductor region similar to the second connection region 18, and on the other side surface, the second connection region 18 may be periodically formed at the second interval dp2.

Also in a case where the first connection region 17 and the second connection region 18 are provided only on one side surface of the trench, the similar effect to that described later can be achieved.

<Operations>

Next, the operation of the semiconductor device 101 according to the first embodiment will be briefly described. In the MOS region 19, when the gate electrode 8 is applied with a voltage equal to or greater than the threshold voltage, the conductivity type is inverted in the body region 3, that is, an n-type channel is formed along the side surface of the gate trench 6. Then, a current path of the same conductivity type (n-type in the first embodiment) is formed between the source electrode 13 and the drain electrode 14, and therefore current flows. The state in which the voltage equal to or greater than the threshold voltage is applied to the gate electrode 8 in this manner becomes an on state of the semiconductor device 101.

On the other hand, when the gate electrode 8 is applied with a voltage equal to or less than the threshold voltage, a channel is not formed in the body region 3, and therefore a current path as in the on state is not formed. Therefore, even if voltage is applied between the drain electrode 14 and the source electrode 13, almost no current flows from the drain electrode 14 to the source electrode 13. The state in which the voltage at the gate electrode 8 is equal to or less than the threshold voltage becomes an off state of the semiconductor device 101.

Then, by controlling the voltage applied to the gate electrode 8, the semiconductor device 101 switches between the on state and the off state. Thus, the semiconductor device 101 has a MOSFET structure including the gate electrode 8, the gate insulating film 7, the drift layer 2, the body region 3, the source region 4, the source electrode 13, and the drain electrode 14 in the MOS region 19.

On the other hand, when the SBD in the SBD region 20 is applied with a forward voltage in the off state of the semiconductor device 101, unipolar current flows between the Schottky electrode 12 and the drain electrode 14. When a bias is further applied, a bipolar current starts to flow through a parasitic pn diode formed in the body region 3, the first bottom protection region 15, or the like. The current value obtained before this parasitic pn diode starts the bipolar operation becomes the maximum unipolar current of the element.

<Method for Producing>

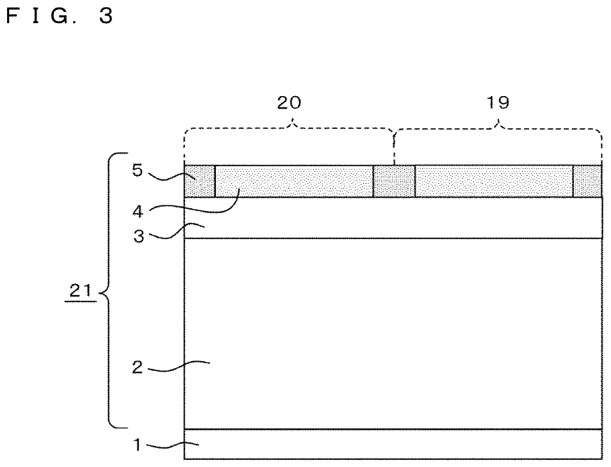

Next, a method for producing the semiconductor device 101 according to the first embodiment will be described. FIGS. 3 to 9 are views showing each process of the method for producing the semiconductor device 101 in the first embodiment. In FIG. 3, first, the substrate 1 on which the n-type semiconductor layer 21 made of silicon carbide is formed is prepared. More specifically, the n-type semiconductor layer 21 only needs to be formed by an epitaxial growth method on the substrate 1 that is an n-type silicon carbide substrate. The n-type impurity concentration of the semiconductor layer 21 is formed so as to correspond to the n-type impurity concentration of the drift layer 2 described above.

Then, the body region 3 is formed by ion implantation in the upper layer portion in the semiconductor layer 21 (drift layer 2), and the source region 4 and the body contact region 5 are selectively formed by ion implantation in the upper layer portion of the body region 3 (semiconductor layer 21 or drift layer 2). In the ion implantation, ions such as nitrogen (N) and phosphorus (P) are implanted as a donor in the case of forming an n-type region, and ions such as aluminum (Al) and boron (B) are implanted as an acceptor in the case of forming a p-type region. The impurity concentration in each region is formed to become the above-described value. The order of forming the body region 3, the source region 4, and the body contact region 5 may be reversed, and all or some regions may be formed by epitaxial growth instead of ion implantation.

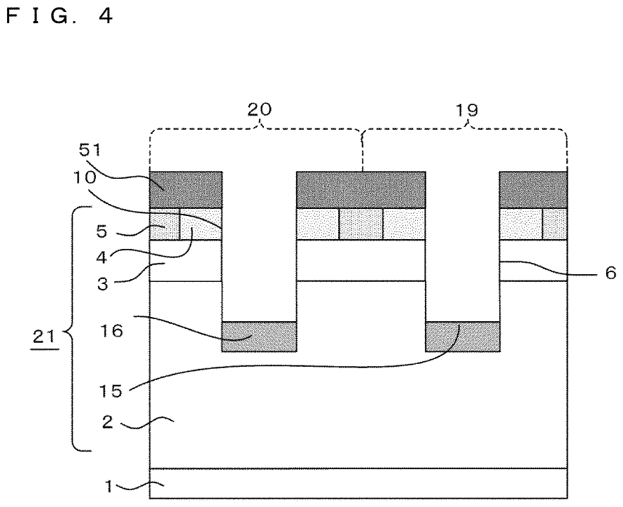

Next, in FIG. 4, using a first mask 51, the gate trench 6 and the Schottky trench 10 that penetrate the source region 4 and the body region 3 from the surface of the semiconductor layer 21 and reach the drift layer 2 are formed by reactive ion etching (RIE). At this time, the width of the gate trench 6 and the width of the Schottky trench 10 may be different from each other. Using a plurality of masks, the gate trench 6 in the MOS region 19 and the Schottky trench 10 in the SBD region 20 may be formed using individual etching processes. In this case, the depth of the gate trench 6 and the depth of the Schottky trench 10 may be different from each other. Then, ion implantation is performed in a direction perpendicular to the surface of the semiconductor layer 21 using the first mask 51 or the like. The first bottom protection region 15 is formed by p-type ion implantation to the bottom of the gate trench 6, and the second bottom protection region 16 is formed by p-type ion implantation to the bottom of the Schottky trench 10.

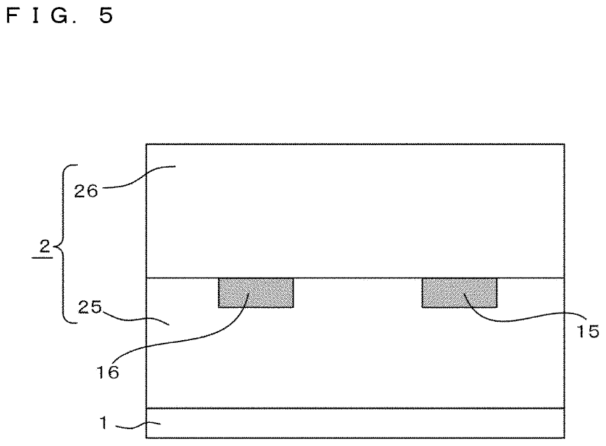

Alternatively, as shown in FIG. 5, after an n-type first drift layer 25 is formed on the substrate 1 by epitaxial growth, the first bottom protection region 15 and the second bottom protection region 16 may be selectively formed by ion implantation in an upper layer portion of the first drift layer 25 in advance or embedded and formed by epitaxial growth. In this case, after the formation of the first bottom protection region 15 and the second bottom protection region 16, an n-type second drift layer 26 is formed by epitaxial growth on the first drift layer 25, the first bottom protection region 15, and the second bottom protection region 16, and then each semiconductor region and trench are formed. For example, the body region 3 is formed in an upper layer portion of the second drift layer 26. The combination of the first drift layer 25 and the second drift layer 26 corresponds to the drift layer 2 described above.

The first bottom protection region 15 and the second bottom protection region 16 may protrude on the drift layer 2 side (direction orthogonal to the thickness direction of the drift layer 2) relative to the side surfaces of the gate trench 6 and the Schottky trench 10. The first bottom protection region 15 and the second bottom protection region 16 may each be formed in the trench by epitaxial growth after the gate trench 6 and the Schottky trench 10 are formed excessively deep by the thickness for forming them.

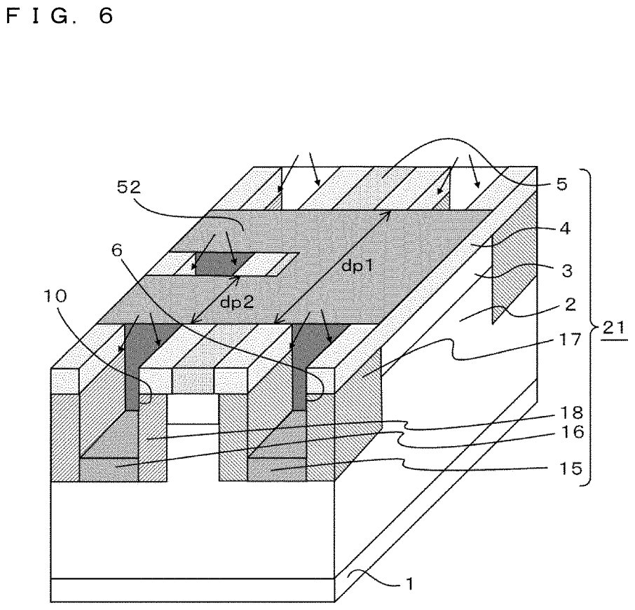

Subsequently, in FIG. 6, the first connection region 17 and the second connection region 18 are formed by performing selective ion implantation using a second mask 52 while having a certain inclination angle. That is, by using the second mask 52, ion implantation is performed in an oblique direction with respect to the side surface of the gate trench 6, and the plurality of first connection regions 17 of the second conductivity type are formed so as to connect the body region 3 and the first bottom protection region 15. By using the second mask 52, ion implantation is performed in an oblique direction with respect to the side surface of the Schottky trench 10, and the plurality of second connection regions 18 of the second conductivity type are formed so as to connect the body region 3 and the second bottom protection region 16.

The second mask 52 is periodically opened at the first interval dp1 in the extension direction of the gate trench 6 in the MOS region 19, and is periodically opened at the second interval dp2 smaller than the first interval dp1 in the extension direction of the Schottky trench 10 in the SBD region 20. By using the second mask 52 having such layout, the first connection region 17 and the second connection region 18 can be simultaneously formed. Different masks may be used at the time of forming the first connection region 17 and at the time of forming the second connection region 18.

Thereafter, the second mask 52 is removed, and the gate insulating film 7 is entirely formed on the semiconductor layer 21, thereby forming the gate insulating film 7 on the bottom and side surface in the gate trench 6.

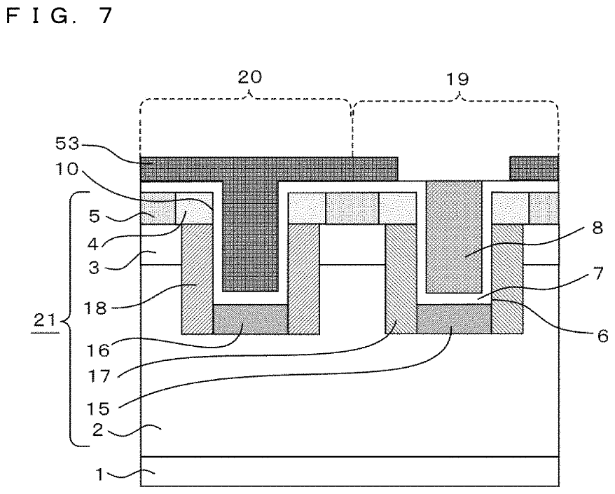

Next, as shown in FIG. 7, a third mask 53 is formed. The third mask 53 covers the SBD region 20 and has an opening at least above the gate trench 6 in the MOS region 19. The gate electrode 8 is formed by filling, for example, polysilicon (Poly-Si) so as to embed the gate trench 6 via the gate insulating film 7 using the third mask 53. The interlayer insulating film 9 is formed so as to cover the gate electrode 8.

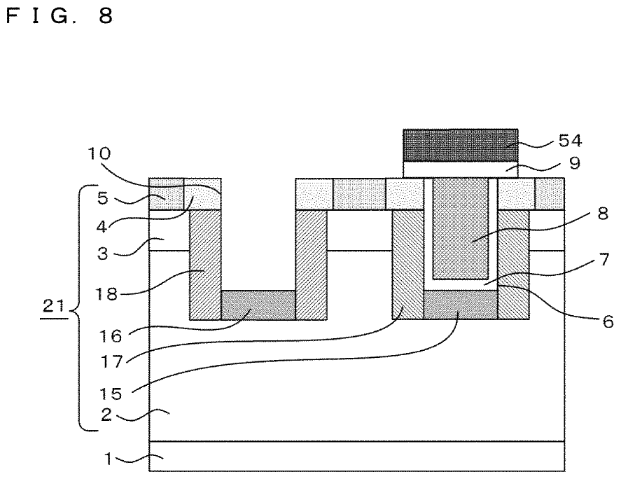

Then, after the third mask 53 is removed by selective etching or the like using a resist mask or the like, a fourth mask 54 is formed on the interlayer insulating film 9 covering the gate trench 6. The gate insulating film 7 is also patterned together with the interlayer insulating film 9 using the fourth mask 54 to expose the surface of the semiconductor layer 21 as shown in FIG. 8. An ohmic electrode not illustrated made of a metal such as nickel (Ni) is formed on the surfaces of the source region 4 and the body contact region 5.

Thereafter, a metal such as titanium (Ti) or molybdenum (Mo) is deposited on the semiconductor layer 21 to form the Schottky electrode 12 in the Schottky trench 10 in the SBD region 20. In the SBD region 20 and the MOS region 19, a metal such as aluminum (Al) is deposited on the Schottky electrode 12, the ohmic electrode, and the interlayer insulating film 9 so as to cover them, thereby forming the source electrode 13. Then, the drain electrode 14 is formed so as to cover the back surface of the substrate 1. Through the above process, the semiconductor device 101 shown in FIG. 1 can be produced.

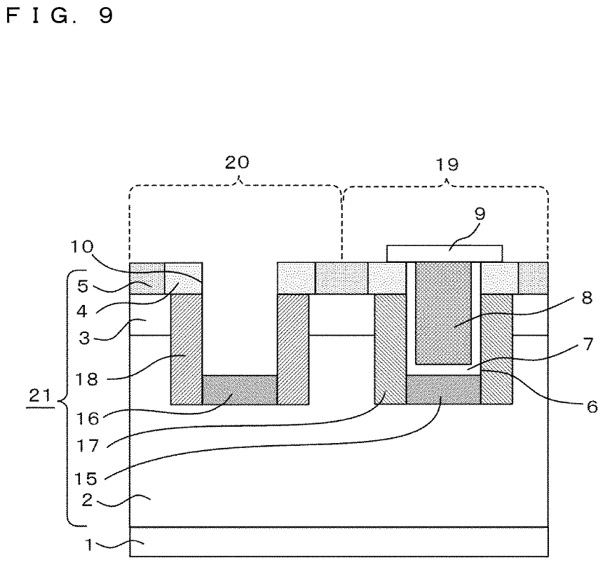

The gate insulating film 7 and the interlayer insulating film 9 are typically both formed as oxide films. Therefore, in FIGS. 8, 9, and other figures, the portion of the gate insulating film 7 protruding to the outside of the gate trench 6 (protruding onto the surface of the semiconductor layer 21) is described as the same layer as the interlayer insulating film 9.

<Features>

Next, features and the like of the semiconductor device 101 according to the first embodiment will be described. The semiconductor device 101 according to the first embodiment is a power switching element in which the SBD as a unipolar freewheeling diode is built in an antiparallel manner in a MOSFET that is a unipolar semiconductor device. Therefore, the cost can be reduced as compared with a case where individual diodes are externally attached and used.

Since the semiconductor device 101 is a MOSFET using silicon carbide (SiC) as a base material of the substrate 1 and the semiconductor layer 21, it is possible to suppress a bipolar operation due to the parasitic pn diode by having the built-in SBD. This is because, in a semiconductor device using silicon carbide, reliability of an element is sometimes impaired due to expansion of crystal defects caused by carrier recombination energy due to parasitic pn diode operation.

The semiconductor device 101 is a so-called trench gate type MOSFET having the gate electrode 8 in the gate trench 6 formed in an element. Therefore, as compared with the planar type MOSFET having the gate electrode 8 on the element surface, a channel can be formed in a side wall portion of the gate trench 6, whereby the channel width density can be improved, and on-resistance can be reduced.

Furthermore, the semiconductor device 101 is a trench gate type MOSFET, and has a structure in which the Schottky electrode 12 is embedded in the Schottky trench 10 in the SBD region 20, and the Schottky interface 22 is formed on the side surface of the Schottky trench 10. Therefore, since both the gate electrode 8 and the Schottky electrode 12 are formed inside the gate trench 6 and the Schottky trench 10, respectively, the distance between the trenches, that is, the cell pitch of each cell can be kept small, and a high current density can be obtained.

On the other hand, in the trench type device structure, there is a problem that electric field concentration occurs at the bottom of the trench when a high voltage is applied in the off state of the semiconductor device. In particular, a trench type silicon carbide semiconductor device has a dielectric breakdown strength having high SiC, and therefore there is a problem that, for the MOS region, a gate insulating film breakdown due to electric field concentration at the trench bottom is likely to occur before avalanche breakdown in the drift layer, and there is a problem that, for the SBD region, a reverse leakage current is likely to increase due to a high electric field at the Schottky interface on the trench side surface.

On the other hand, in the semiconductor device 101 according to the first embodiment, the first connection region 17 is formed on the side of the gate trench 6 in the MOS region 19, Since a depletion layer is formed around the first connection region 17, the electric field strength of the portion decreases. Therefore, in the MOS region 19, it is possible to suppress occurrence of dielectric breakdown of the gate insulating film 7 due to electric field concentration at the bottom of the gate trench 6.

In the MOS region 19, since the first connection region 17 electrically connects the first bottom protection region 15 and the source electrode 13, the carrier in the depletion layer extending from the first bottom protection region 15 easily flows, and there is an effect of improving switching characteristics.

On the other hand, since the first connection region 17 is formed on the side of the gate trench 6, no channel is formed in the portion where the first connection region 17 is formed. Since JFET resistance is generated around the first connection region 17 simultaneously with the formation of the depletion layer, when the first interval dp1 of the first connection region 17 is reduced, the JFET resistance in the region between the first connection regions 17 increases. In order to prevent an increase in the on-resistance due to this, it is desirable that the total area forming the first connection region 17 is minimum enough to maintain electrical connection between the first bottom protection region 15 and the source electrode 13. The first interval dp1 of the first connection region 17 is desirably set to a maximum value at which the effect of improving the switching characteristics can be obtained. Since the value of the current flowing through the first connection region 17 is proportional to the area of the first connection region 17, the area of the first connection region 17 at which electrical connection can be maintained in consideration of other parameters and the like is calculated.

In the SBD region 20, by forming the second connection region 18 on the side of the Schottky trench 10, the electric field of the Schottky interface 22 can be reduced by the depletion layer extending around the second connection region 18, and the increase in the leakage current can be suppressed. The smaller the second interval dp2 of the second connection region 18 is, the higher the effect of electric field relaxation is.

On the other hand, since the second connection region 18 is formed on the side of the Schottky trench 10, the Schottky interface 22 is not formed at the portion where the second connection region 18 is formed. Therefore, the region between the second connection regions 18 needs to be an area where a necessary unipolar current value can be obtained, but this becomes trade-off with the leakage current. Therefore, the interval dp2 between the second connection regions 18 is desirably set to a minimum value at which a sufficient unipolar current can be obtained. Since the value of current desired to flow through the SBD varies for each semiconductor device, the required unipolar current value is determined by the specifications of the device.

As described above, by widening the first interval dp1 between the first connection regions 17 on the side of the gate trench 6 in the MOS region 19, it is possible to reduce the HET resistance between the first connection regions 17 and reduce the on-resistance, and by narrowing the second interval dp2 between the second connection regions 18 on the side of the Schottky trench 10 in the SBD region 20, it is possible to reduce the electric field strength of the Schottky interface 22 between the second connection regions 18. That is, by making the second interval dp2 between the second connection regions 18 smaller than the first interval dp1 between the first connection regions 17, it is possible to suppress the increase in the leakage current via the Schottky interface 22 at the time of device-off while reducing the on-resistance at the time of device-on. Thus, by changing the layouts of the first connection region 17 and the second connection region 18 between the MOS region 19 and the SBD region 20, it is possible to improve the trade-off between the on-resistance of the MOSFET and the leakage current of the SBD.

In the semiconductor device 101 of the first embodiment, since the drift layer 2 has the main surface provided with an off angle larger than 0° in the <11-20> axis direction, and the gate trench 6 and the Schottky trench 10 are provided in parallel to the <11-20> axis direction, variations in characteristics due to the trench side surfaces can be reduced, and the operation of the semiconductor device 101 can be stabilized.

<Modifications>

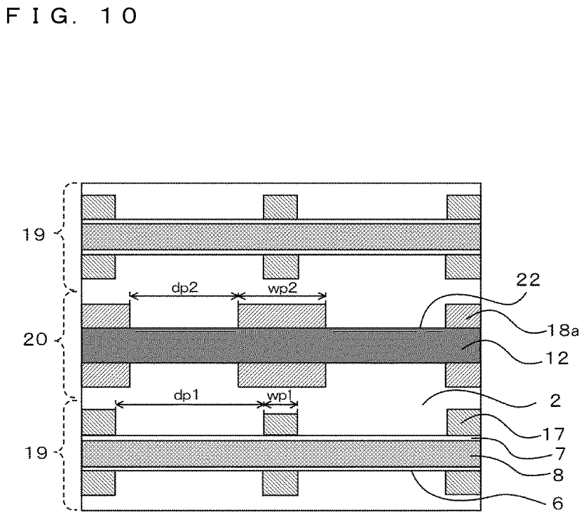

Next, modifications of the semiconductor device 101 according to the first embodiment will be described. FIG. 10 is a schematic plan view schematically showing the layout of each semiconductor region in a semiconductor device 102 of the first modification. FIG. 10 corresponds to a view of a cross section in a lateral direction at a certain depth between the body region 3 and the first bottom protection region 15 shown in FIG. 1 as viewed from above.

As shown in FIG. 10, in the semiconductor device 102 according to the first modification, the first connection region 17 is formed in the MOS region 19, and a second connection region 18a is formed in the SBD region 20. The second connection region 18a is formed such that its width wp2 becomes larger than a width wp1 of the first connection region 17. That is, the length of each of the second connection regions 18a in the extension direction of the Schottky trench 10 is longer than the length of each of the first connection regions 17 in the extension direction of the gate trench 6. Due to this, in a layout in which the formation cycle of the first connection region 17 and the formation cycle of the second connection region 18a are the same, the second interval dp2 of the second connection region 18a can be made smaller than the first interval dp1 of the first connection region 17. Other configurations and the like are similar to those of the semiconductor device 101 shown in FIG. 1 and the like.

Also in the semiconductor device 102 according to the first modification, effects similar to those described in the first embodiment can be achieved. According to the semiconductor device 102 of the first modification, even when the formation cycles of the first connection region 17 and the second connection region 18a are the same, by forming the width wp2 of the second connection region 18a to become larger than the width wp1 of the first connection region 17, it is possible to make the first interval dp1 of the first connection region 17 smaller than the second interval dp2 of the second connection region 18a and improve the trade-off between the on-resistance of the MOSFET and the leakage current of the SBD.

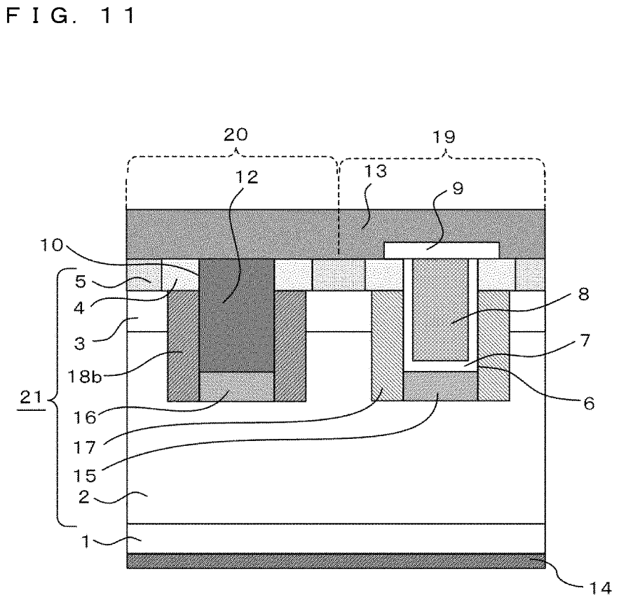

FIG. 11 is a schematic cross sectional view showing a cross section of a part of a cell region in a semiconductor device 103 of the second modification. As shown in FIG. 11, in the semiconductor device 103 according to the second modification, the first connection region 17 is formed in the MOS region 19, and a second connection region 18b is formed in the SBD region 20. The second connection region 18b is formed such that the p-type impurity concentration becomes higher than that of the first connection region 17. Other configurations and the like are similar to those of the semiconductor device 101 shown in FIG. 1 and the like.

Also in the semiconductor device 103 according to the second modification, effects similar to those described in the first embodiment can be achieved.

In the semiconductor device 101 of the first embodiment, when the width of the Schottky trench 10 in the SBD region 20 is equal to or greater than the width of the gate trench 6 in the MOS region 19, the equipotential line near the bottom of the second bottom protection region 16 becomes equal to or gentler than the equipotential line near the bottom of the first bottom protection region 15, and therefore the electric field strength applied to the second bottom protection region 16 becomes equal to or less than the electric field strength applied to the first bottom protection region 15. Also when the depth of the Schottky trench 10 in the SBD region 20 is equal to or shallower than the depth of the gate trench 6 in the MOS region 19, the length of the drift layer 2 present below the second bottom protection region 16 becomes equal to or greater than the length of the drift layer 2 present below the first bottom protection region 15, and therefore the electric field strength applied to the second bottom protection region 16 becomes equal to or less than the electric field strength applied to the first bottom protection region 15.

Furthermore, as described above, in the semiconductor device 101, since the second interval dp2 between the second connection regions 18 is smaller than the first interval dp1 between the first connection regions 17, the electric field strength of the Schottky interface 22 is reduced, and at the same time, the electric field applied to pn junction at the end portion of the second connection region 18 is also relaxed. Due to this, the maximum electric field strength at the end portion of the second connection region 18 becomes lower than the maximum electric field strength at the end portion of the first connection region 17. Therefore, the impurity concentration of the second connection region 18 can be increased by the lower maximum electric field strength at the end portion of the second connection region 18.

The semiconductor device 103 according to the second modification can increase the impurity concentration of the second connection region 18b to enhance the electric field relaxation effect around the second connection region 18b and reduce the leakage current while avoiding the deterioration of the withstand voltage at the element due to an increase in the electric field strength applied to the end portion of the second connection region 18b.

In the first embodiment, the first modification, and the second modification described above, the gate trench 6 and the Schottky trench 10 are formed in a stripe shape in a plan view. However, the present invention is not limited to this. For example, the arrangement of the gate trench 6 and the Schottky trench 10 may have a lattice shape. In this case, for a specific side surface among the four side surfaces of the trench, the side surface has a large area, and a plurality of the first connection regions 17 or the second connection regions 18 (the second connection region 18a and the second connection region 18b) are formed at the first interval dp1 or the second interval dp2, whereby the above-described various effects can be achieved.

### Second Embodiment

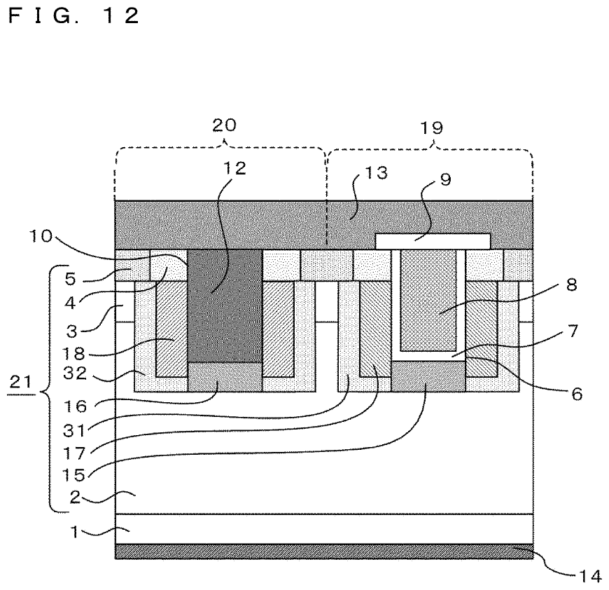

FIG. 12 is a schematic cross sectional view showing a cross section of a part of a cell region in a semiconductor device 201 of the second embodiment. In the semiconductor device 201 of the second embodiment, unlike the semiconductor device 101 of the first embodiment, a first electric field relaxation region 31 and a second electric field relaxation region 32 are formed in the MOS region 19 and the SBD region 20, respectively. Since the semiconductor device 201 of the second embodiment is mostly common to the semiconductor device 101 of the first embodiment, differences from the semiconductor device 101 will be mainly described below, and the description of configurations and the like common to those of the semiconductor device 101 will be omitted as appropriate.

The first electric field relaxation region 31 is a p-type semiconductor region provided below the first connection region 17 and having a p-type impurity concentration lower than that of the first connection region 17. As shown in FIG. 12, the first electric field relaxation region 31 is provided below and on the side of the first connection region 17. More specifically, the first electric field relaxation region 31 is provided in contact with the lower portion and the side surface of the first connection region 17, and is formed so as to cover the lower portion and the side surface of the first connection region 17. The first electric field relaxation region 31 is formed so as to be in contact with the first connection region 17 and the first bottom protection region 15.

The second electric field relaxation region 32 is a p-type semiconductor region provided below the second connection region 18 and having a p-type impurity concentration lower than that of the second connection region 18. As shown in FIG. 12, the second electric field relaxation region 32 is provided below and on the side of the second connection region 18. More specifically, the second electric field relaxation region 32 is provided in contact with the lower portion and the side surface of the second connection region 18, and is formed so as to cover the lower portion and the side surface of the second connection region 18. The second electric field relaxation region 32 is formed so as to be in contact with the second connection region 18 and the second bottom protection region 16. Other configurations are similar to those of the semiconductor device 101 of the first embodiment.

FIG. 12 illustrates a case where the first electric field relaxation region 31 in the MOS region 19 and the second electric field relaxation region 32 in the SBD region 20 are separated from each other, but they may be in contact with each other.

The first electric field relaxation region 31 is not limited to that formed so as to be in contact with the first connection region 17 and the first bottom protection region 15 and cover the lower portion and the side surface of the first connection region 17, and may be provided below away from the lower portion of the first connection region 17 in the drift layer 2, or may be provided at a position away from the side surfaces of the first connection region 17 or the first bottom protection region 15 in the drift layer 2.

Similarly, the second electric field relaxation region 32 is not limited to that formed so as to be in contact with the second connection region 18 and the second bottom protection region 16 and cover the lower portion and the side surface of the second connection region 18, and may be provided below away from the lower portion of the second connection region 18 in the drift layer 2, or may be provided at a position away from the side surfaces of the second connection region 18 and the second bottom protection region 16 in the drift layer 2.

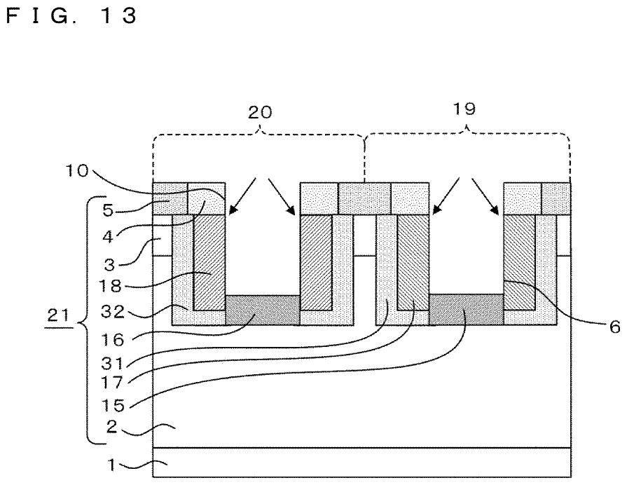

Next, a method for producing the semiconductor device 201 will be described. FIG. 13 is a view showing some processes of the method for producing the semiconductor device 201 in the second embodiment. First, similarly to the method for producing the semiconductor device 101 described in the first embodiment, after the gate trench 6, the Schottky trench 10, the first bottom protection region 15, and the second bottom protection region 16 are formed as shown in FIG. 4, the first electric field relaxation region 31 and the second electric field relaxation region 32 are formed by inclined ion implantation such as aluminum (Al) and boron (B) from the inner walls of the gate trench 6 and the Schottky trench 10 as shown in FIG. 13.

Thereafter, inclined ion implantation with implantation energy lower than that at the time of forming the first electric field relaxation region 31 and the second electric field relaxation region 32 is performed similarly from the inner walls of the gate trench 6 and the Schottky trench 10, thereby forming the first connection region 17 and the second connection region 18. This makes it possible to form the first electric field relaxation region 31 and the second electric field relaxation region 32 between the first connection region 17 and the drift layer 2 and between the second connection region 18 and the drift layer 2, respectively. Other parts can be produced similarly to the semiconductor device 101 of the first embodiment.

Also in the semiconductor device 201 of the second embodiment, effects similar to those described in the first embodiment can be achieved.

In the semiconductor device 101, the electric field tends to concentrate on the end portions of the first connection region 17 and the second connection region 18 formed on the sides of the gate trench 6 and the Schottky trench 10. In particular, the more the distance between the first connection region 17 and the second connection region 18 facing each other in the direction perpendicular to the extension directions of the gate trench 6 and the Schottky trench 10, the first interval dp1 between the first connection regions 17 in the extension direction of the gate trench 6, and the second interval dp2 between the second connection regions 18 in the extension direction of the Schottky trench 10 increase, the higher the electric fields of the end portion of the first connection region 17 and the end portion of the second connection region 18 become, and the withstand voltage at the element may deteriorate.

Therefore, in the semiconductor device 201 of the second embodiment, the first electric field relaxation region 31 having a p-type impurity concentration lower than that of the first connection region 17 is formed between the first connection region 17 and the drift layer 2. The second electric field relaxation region 32 having a p-type impurity concentration lower than that of the second connection region 18 is formed between the second connection region 18 and the drift layer 2. This makes it possible to reduce the electric field strengths at the end portion of the first connection region 17 and the end portion of the second connection region 18, and improve the withstand voltage at the element. In particular, since the first electric field relaxation region 31 is formed below the first connection region 17 and the second electric field relaxation region 32 is formed below the second connection region 18, the electric field strengths in the lower portion of the first connection region 17 and the lower portion of the second connection region 18 can be further reduced.

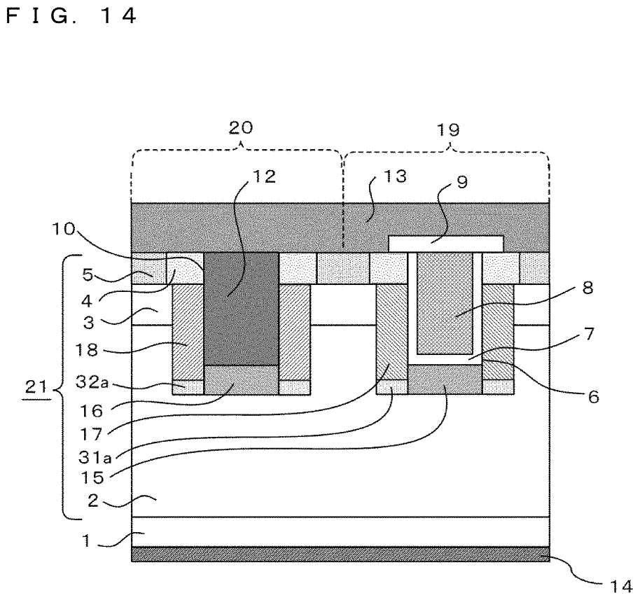

Next, modifications of the semiconductor device 201 according to the second embodiment will be described. FIG. 14 is a schematic cross sectional view showing a cross section of a part of a cell region in a semiconductor device 202 of the first modification. In the semiconductor device 202 according to the first modification, as shown in FIG. 14, a first electric field relaxation region 31a is not provided on the side of the first connection region 17 but is provided below the first connection region 17. As shown in FIG. 14, a second electric field relaxation region 32a is not provided on the side of the second connection region 18 but is provided below the second connection region 18. More specifically, the first electric field relaxation region 31a is provided in contact with the lower portion of the first connection region 17 and the side surface of the first bottom protection region 15, and is formed so as to cover the lower portion of the first connection region 17. The second electric field relaxation region 32a is provided in contact with the lower portion of the second connection region 18 and the side surface of the second bottom protection region 16, and is formed so as to cover the lower portion of the second connection region 18. Other configurations are similar to those of the semiconductor device 201 shown in FIG. 12 and the like.

The first electric field relaxation region 31a is not limited to that formed so as to be in contact with the first connection region 17 and the first bottom protection region 15 and cover the lower portion of the first connection region 17, and may be provided below away from the lower portion of the first connection region 17 in the drift layer 2 or may be provided at a position away from the side surface of the first bottom protection region 15 in the drift layer 2.

Similarly, the second electric field relaxation region 32a is not limited to that formed so as to be in contact with the second connection region 18 and the second bottom protection region 16 and cover the lower portion of the second connection region 18, and may be provided below away from the lower portion of the second connection region 18 in the drift layer 2 or may be provided at a position away from the side surface of the second bottom protection region 16 in the drift layer 2.

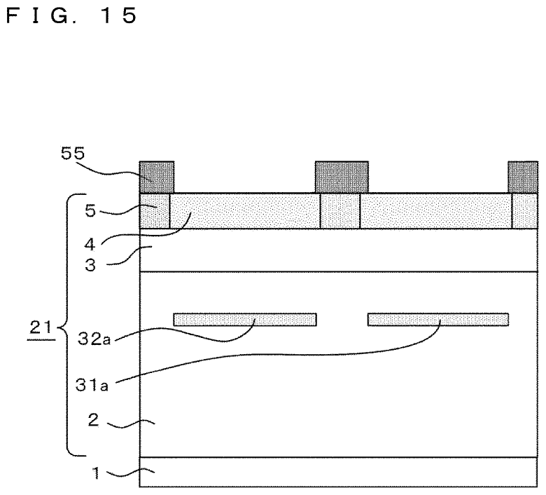

Next, a method for producing the semiconductor device 202 according to the first modification will be described. FIGS. 15 to 17 are views showing some processes of the method for producing the semiconductor device 202 according to the first modification. First, similarly to the method for producing the semiconductor device 101 described in the first embodiment, the body region 3, the source region 4, and the body contact region 5 are formed as shown in FIG. 3, and then a fifth mask 55 having an opening wider than those of the gate trench 6 and the Schottky trench 10 formed in a subsequent process is formed on the semiconductor layer 21 as shown in FIG. 15. Then, ion implantation is performed in a direction perpendicular to the surface of the semiconductor layer 21 to form the first electric field relaxation region 31a and the second electric field relaxation region 32a.

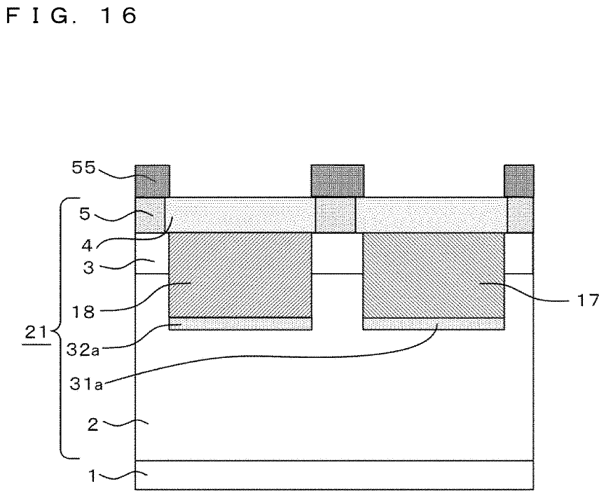

Subsequently, as shown in FIG. 16, ion implantation with implantation energy lower than that at the time of forming the first electric field relaxation region 31a and the second electric field relaxation region 32a is performed in a direction perpendicular to the surface of the semiconductor layer 21 to form the first connection region 17 on the first electric field relaxation region 31a and form the second connection region 18 on the second electric field relaxation region 32a.

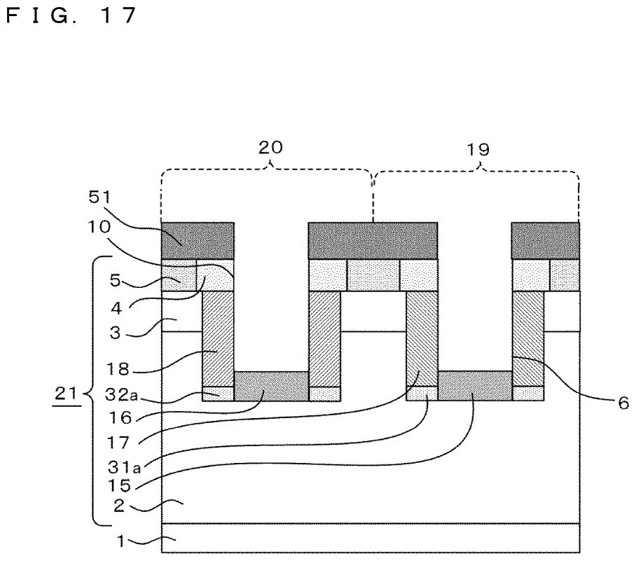

After the fifth mask 55 is removed, as shown in FIG. 17, the first mask 51 having an opening narrower than that of the fifth mask 55 (the first connection region 17 and the second connection region 18) is formed on the semiconductor layer 21. The opening of the first mask 51 is formed so as to be positioned on the first connection region 17 and the second connection region 18. Then, using the first mask 51, the gate trench 6 and the Schottky trench 10 that penetrate the source region 4 and the body region 3 from the surface of the semiconductor layer 21 and reach the drift layer 2 are formed by reactive ion etching (RIE). At this time, as shown in FIG. 17, the gate trench 6 and the Schottky trench 10 are formed such that the trench bottom becomes shallower than the lower portions of the first connection region 17 and the second connection region 18. Furthermore, by using the first mask 51, ion implantation is performed in a direction perpendicular to the surface of the semiconductor layer 21 to form the first bottom protection region 15 at the bottom of the gate trench 6 and for the second bottom protection region 16 at the bottom of the Schottky trench 10.

By doing this, it is possible to form the first electric field relaxation region 31a in the lower portion of the first connection region 17, and form the second electric field relaxation region 32a in the lower portion of the second connection region 18. Other parts can be produced similarly to the semiconductor device 101 of the first embodiment.

Also in the semiconductor device 202 according to the first modification, effects similar to those described in the first embodiment and the second embodiment can be achieved.

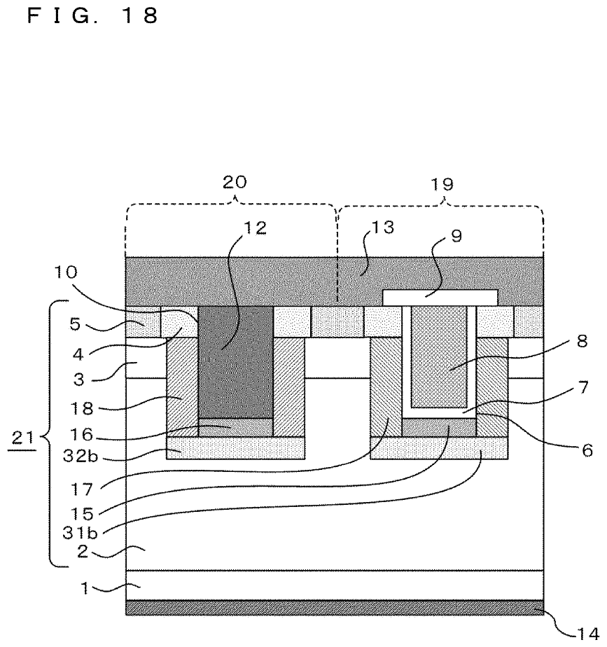

FIG. 18 is a schematic cross sectional view showing a cross section of a part of a cell region in a semiconductor device 203 of the second modification. In the semiconductor device 203 according to the second modification, as shown in FIG. 18, a first electric field relaxation region 31b is also provided below the first bottom protection region 15. As shown in FIG. 18, a second electric field relaxation region 32b is also provided below the second bottom protection region 16. More specifically, the first electric field relaxation region 31b is provided below the gate trench 6 from one side surface to the other side surface of both side surfaces of the gate trench 6 facing each other, and is limited so as to be in contact with the lower portion of the first connection region 17 and the lower portion of the first bottom protection region 15 and cover the lower portion of the first connection region 17 and the lower portion of the first bottom protection region 15. The second electric field relaxation region 32b is provided below the Schottky trench 10 from one side surface to the other side surface of both side surfaces of the Schottky trench 10 facing each other, and is formed so as to be in contact with the lower portion of the second connection region 18 and the lower portion of the second bottom protection region 16 and cover the lower portion of the second connection region 18 and the lower portion of the second bottom protection region 16. Other configurations are similar to those of the semiconductor device 201 shown in FIG. 12 and the like.

The first electric field relaxation region 31b is not limited to that formed so as to be in contact with the first connection region 17 and the first bottom protection region 15 and to cover the lower portion of the first connection region 17 and the lower portion of the first bottom protection region 15, and may be provided below away from the lower portion of the first connection region 17 and the lower portion of the first bottom protection region 15 in the drift layer 2.

Similarly, the second electric field relaxation region 32b is not limited to that formed so as to be in contact with the second connection region 18 and the second bottom protection region 16 and to cover the lower portion of the second connection region 18 and the lower portion of the second bottom protection region 16, and may be provided below away from the lower portion of the second connection region 18 and the lower portion of the second bottom protection region 16 in the drift layer 2.

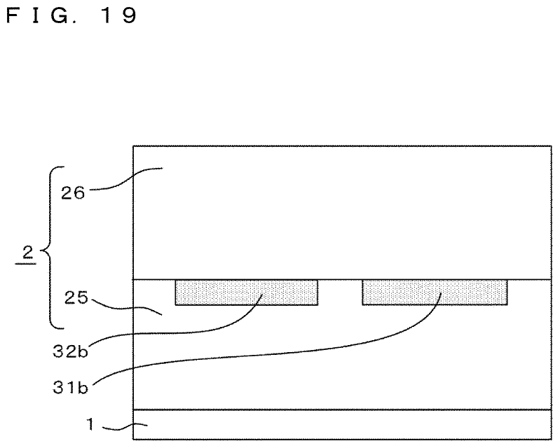

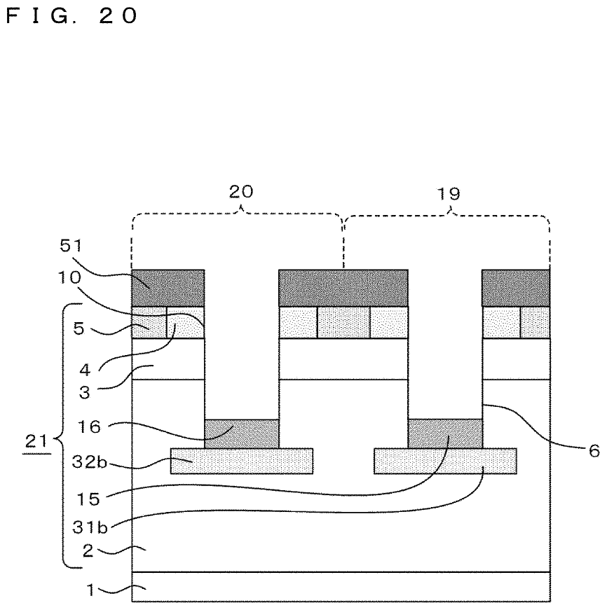

Next, a method for producing the semiconductor device 203 according to the second modification will be described. FIGS. 19 and 20 are views showing some processes of the method for producing the semiconductor device 203 according to the second modification. In the semiconductor device 203, the first electric field relaxation region 31b and the second electric field relaxation region 32b can be formed similarly to the method for producing shown in FIG. 5 of the first embodiment before the process of forming the first bottom protection region 15 and the second bottom protection region 16. That is, as shown in FIG. 19, after the n-type first drift layer 25 is formed on the substrate 1 by epitaxial growth, the first electric field relaxation region 31b and the second electric field relaxation region 32b can be selectively formed by ion implantation in the upper layer portion of the first drift layer 25 in advance, or can be embedded and formed by epitaxial growth.

Subsequently, after the n-type second drift layer 26 is formed by epitaxial growth on the first drift layer 25, the first electric field relaxation region 31b, and the second electric field relaxation region 32b, the body region 3, the source region 4, and the body contact region 5 are formed similarly to the method for producing shown in FIG. 3 of the first embodiment.

Next, as shown in FIG. 20, the first mask 51 having an opening narrower than that of the first electric field relaxation region 31b and the second electric field relaxation region 32b is formed on the semiconductor layer 21. The opening of the first mask 51 is formed so as to be positioned on the first electric field relaxation region 31b and the second electric field relaxation region 32b. Then, using the first mask 51, the gate trench 6 and the Schottky trench 10 that penetrate the source region 4 and the body region 3 from the surface of the semiconductor layer 21 and reach the drift layer 2 are formed by reactive ion etching (RIE). At this time, as shown in FIG. 20, the gate trench 6 and the Schottky trench 10 are formed such that the trench bottom becomes shallower than the upper portions of the first electric field relaxation region 31b and the second electric field relaxation region 32b. Furthermore, by using the first mask 51, ion implantation is performed in a direction perpendicular to the surface of the semiconductor layer 21 to form the first bottom protection region 15 at the bottom of the gate trench 6 and for the second bottom protection region 16 at the bottom of the Schottky trench 10.

By doing this, it is possible to form the first electric field relaxation region 31b so as to cover the lower portions of the first connection region 17 and the first bottom protection region 15, and to form the second electric field relaxation region 32b so as to cover the lower portions of the second connection region 18 and the second bottom protection region 16. Other parts can be produced similarly to the semiconductor device 101 of the first embodiment.

The first bottom protection region 15 and the second bottom protection region 16 may also be formed in the upper layer portion of the first drift layer 25 in advance. In this case, in FIG. 19, after the first electric field relaxation region 31b and the second electric field relaxation region 32b are selectively formed by ion implantation or embedded and formed by epitaxial growth, the first bottom protection region 15 and the second bottom protection region 16 are formed similarly to the method for producing described in FIG. 5. At this time, the first bottom protection region 15 is formed so as to be positioned in the upper layer portion of the first electric field relaxation region 31b, and the second bottom protection region 16 is formed so as to be positioned in the upper layer portion of the second electric field relaxation region 32b. Subsequently, the n-type second drift layer 26 is formed by epitaxial growth on the first drift layer 25, the first bottom protection region 15, the second bottom protection region 16, the first electric field relaxation region 31b, and the second electric field relaxation region 32b, and thereafter, each semiconductor region and trench can be formed by the same method for producing as described above.

Also in the semiconductor device 203 according to the second modification, effects similar to those described in the first embodiment and the second embodiment can be achieved. Furthermore, in the semiconductor device 203, since the first electric field relaxation region 31b and the second electric field relaxation region 32b are formed not only below the first connection region 17 and below the second connection region 18 but also below the first bottom protection region 15 and below the second bottom protection region 16, the electric field strengths at the lower portion of the first bottom protection region 15 and the lower portion of the second bottom protection region 16 can be further reduced.

### Third Embodiment

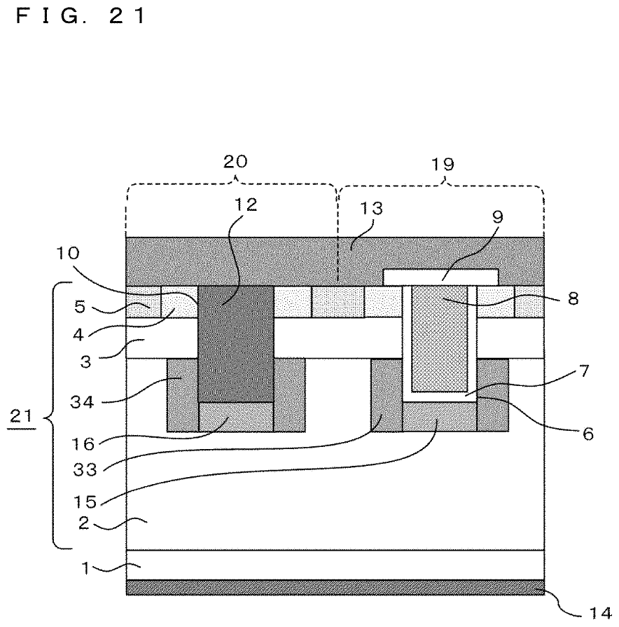

FIG. 21 is a schematic cross sectional view showing a cross section of a part of a cell region in a semiconductor device 301 of the third embodiment. In the semiconductor device 301 of the third embodiment, unlike the semiconductor device 101 of the first embodiment and the semiconductor device 201 of the second embodiment, a first low-resistance region 33 and a second low-resistance region 34 are formed in the MOS region 19 and the SBD region 20, respectively. Since the semiconductor device 301 of the third embodiment is mostly common to the semiconductor device 101 of the first embodiment, differences from the semiconductor device 101 will be mainly described below, and the description of configurations and the like common to those of the semiconductor device 101 will be omitted as appropriate.

As described later, the first low-resistance region 33 is an n-type semiconductor region provided between the first connection regions 17 in the extension direction of the gate trench 6 and having an n-type impurity concentration higher than that of the drift layer 2. As shown in FIG. 21, the first low-resistance region 33 is provided on the side of the gate trench 6. More specifically, the first low-resistance region 33 is formed so as to be in contact with the side surface of the gate trench 6. The first low-resistance region 33 is formed so as to be in contact with the body region 3 and the first bottom protection region 15.

As described later, the second low-resistance region 34 is an n-type semiconductor region provided between the second connection regions 18 in the extension direction of the Schottky trench 10 and has an n-type impurity concentration higher than that of the drift layer 2. As shown in FIG. 21, the second low-resistance region 34 is provided on the side of the Schottky trench 10. More specifically, the second low-resistance region 34 is formed so as to be in contact with the side surface of the Schottky trench 10. The second low-resistance region 34 is formed so as to be in contact with the body region 3 and the second bottom protection region 16.

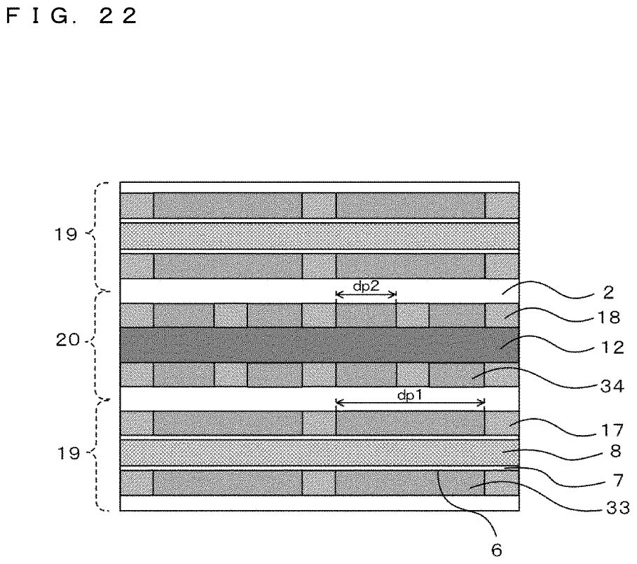

FIG. 22 is a schematic plan view schematically showing the layout of each semiconductor region in the semiconductor device 301 of the third embodiment. FIG. 22 corresponds to a view of a cross section in a lateral direction at a certain depth between the body region 3 and the first bottom protection region 15 shown in FIG. 21 as viewed from above.

As shown in FIG. 22, the first low-resistance region 33 is provided between the first connection regions 17 in the extension direction of the gate trench 6. The first low-resistance region 33 is formed so as to fill the entire region between the adjacent first connection regions 17 in the extension direction of the gate trench 6. The first low-resistance region 33 is formed so as to be in contact with each of the plurality of first connection regions 17 provided.

As shown in FIG. 22, the second low-resistance region 34 is provided between the second connection regions 18 in the extension direction of the Schottky trench 10. The second low-resistance region 34 is formed so as to fill the entire region between the adjacent second connection regions 18 in the extension direction of the Schottky trench 10. The second low-resistance region 34 is formed so as to be in contact with each of the plurality of second connection regions 18 provided. Other configurations are similar to those of the semiconductor device 101 of the first embodiment.

FIGS. 21 and 22 illustrate a case where the first low-resistance region 33 in the MOS region 19 and the second low-resistance region 34 in the SBD region 20 are separated from each other, but they may be in contact with each other.

The first low-resistance region 33 is not limited to that provided on each of the both side surfaces of the gate trench 6 facing each other, and may be formed only on any one of the side surfaces. The first low-resistance region 33 needs not be formed in the entire region between the first connection regions 17 adjacent in the extension direction of the gate trench 6, and may be partially formed such as only a partial region.

Similarly, the second low-resistance region 34 is not limited to that provided on each of the both side surfaces of the Schottky trench 10 facing each other, and may be formed only on any one of the side surfaces. The second low-resistance region 34 needs not be formed in the entire region between the second connection regions 18 adjacent in the extension direction of the Schottky trench 10, and may be partially formed such as only a partial region.

The first low-resistance region 33 is not limited to that provided in contact with the side surface of the gate trench 6, and may be provided at a position away from the side surface of the gate trench 6 in the drift layer 2. Similarly, the second low-resistance region 34 is also not limited to that provided in contact with the side surface of the Schottky trench 10, and may be provided at a position away from the side surface of the Schottky trench 10 in the drift layer 2.

The first low-resistance region 33 is not limited to that provided in contact with the body region 3, the first connection region 17, and the first bottom protection region 15, and may be provided at a position away from these regions in the drift layer 2. Similarly, the second low-resistance region 34 is also not limited to that provided in contact with the body region 3, the second connection region 18, and the second bottom protection region 16, and may be provided at a position away from these regions in the drift layer 2.

Next, a method for producing the semiconductor device 301 will be described. First, similarly to the method for producing the semiconductor device 101 described in the first embodiment, as shown in FIG. 4, after the gate trench 6, the Schottky trench 10, the first bottom protection region 15, and the second bottom protection region 16 are formed, with the first mask 51 remaining formed or after the first mask 51 is removed, the first low-resistance region 33 and the second low-resistance region 34 are formed by inclined ion implantation of nitrogen (N), phosphorus (P), or the like from the inner walls of the gate trench 6 and the Schottky trench 10. Here, the first low-resistance region 33 and the second low-resistance region 34 are formed such that the n-type impurity concentration in these regions becomes lower than the p-type impurity concentration of the body region 3. By doing this, it is possible to prevent the conductivity type of the body region 3 from being inverted to the n-type.

Thereafter, the first connection region 17 and the second connection region 18 are formed similarly to the method for producing shown in FIG. 6. The first connection region 17 and the second connection region 18 are formed such that the p-type impurity concentration in these regions becomes higher than the n-type impurity concentration of the first low-resistance region 33 and the second low-resistance region 34. By doing this, it is possible to form the first connection region 17 and the second connection region 18 by inverting the conductivity type of the regions that were originally the first low-resistance region 33 and the second low-resistance region 34 to the p-type. Since the first connection region 17 and the second connection region 18 are set such that the p-type impurity concentration becomes higher than that of the normal body region 3, the first connection region 17 and the second connection region 18 are formed in a region that was originally the body region 3.

By doing this, it is possible to form the first low-resistance region 33 so as to cover the side surface of the gate trench 6 between the first connection regions 17, and form the second low-resistance region 34 so as to cover the side surface of the Schottky trench 10 between the second connection regions 18. Other parts can be produced similarly to the semiconductor device 101 of the first embodiment.

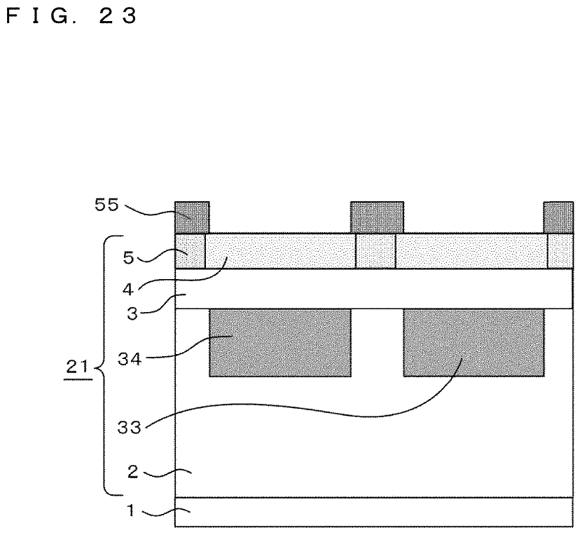

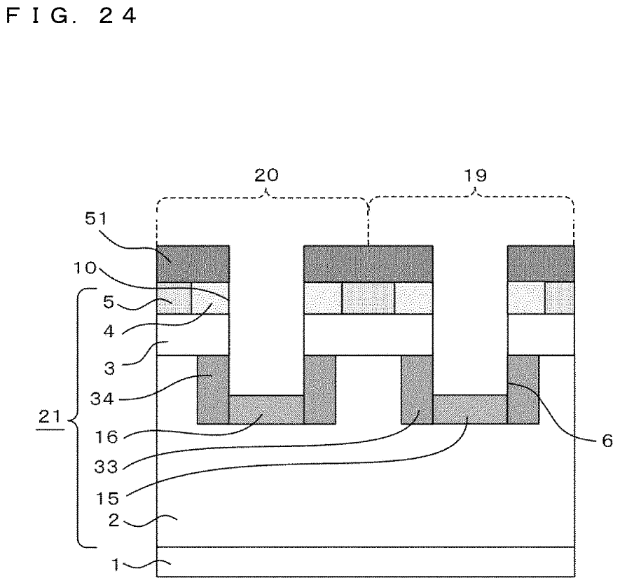

The first low-resistance region 33 and the second low-resistance region 34 may be formed similarly to the method for producing shown in FIGS. 15 and 16. FIGS. 23 and 24 are views showing some processes of the method for producing the semiconductor device 301 in the third embodiment. First, similarly to the method for producing the semiconductor device 101 described in the first embodiment, as shown in FIG. 3, after the body region 3, the source region 4, and the body contact region 5 are formed, the fifth mask 55 having an opening wider than that of the gate trench 6 and the Schottky trench 10 formed in a subsequent process is formed on the semiconductor layer 21 as shown in FIG. 23. Then, ion implantation is performed in a direction perpendicular to the surface of the semiconductor layer 21 to form the first low-resistance region 33 and the second low-resistance region 34.

After the fifth mask 55 is removed, as shown in FIG. 24, the first mask 51 having an opening narrower than that of the fifth mask 55 (the first low-resistance region 33 and the second low-resistance region 34) is formed on the semiconductor layer 21. The opening of the first mask 51 is formed so as to be positioned on the first low-resistance region 33 and the second low-resistance region 34. Then, using the first mask 51, the gate trench 6 and the Schottky trench 10 that penetrate the source region 4 and the body region 3 from the surface of the semiconductor layer 21 and reach the drift layer 2 are formed by reactive ion etching (RIE). At this time, as shown in FIG. 24, the gate trench 6 and the Schottky trench 10 are formed such that the trench bottom becomes shallower than the lower portions of the first low-resistance region 33 and the second low-resistance region 34. Furthermore, by using the first mask 51, ion implantation is performed in a direction perpendicular to the surface of the semiconductor layer 21 to form the first bottom protection region 15 at the bottom of the gate trench 6 and for the second bottom protection region 16 at the bottom of the Schottky trench 10.

Thereafter, the first connection region 17 and the second connection region 18 are formed similarly to the method for producing shown in FIG. 6. Other parts can be produced similarly to the semiconductor device 101 of the first embodiment.

Also in the semiconductor device 301 of the third embodiment, effects similar to those described in the first embodiment can be achieved.

In the semiconductor device 301 of the third embodiment, since the first low-resistance region 33 having an n-type impurity concentration higher than that of the drift layer 2 is formed adjacent to the first connection region 17, the resistance around the first connection region 17 is reduced, and the on-resistance of the MOSFET can be reduced. Since the second low-resistance region 34 having an n-type impurity concentration higher than that of the drift layer 2 is formed adjacent to the second connection region 18, the resistance around the second connection region 18 is reduced at the time of operation of the SBD, and a high Schottky current can be obtained.

Furthermore, since the first low-resistance region 33 and the second low-resistance region 34 are formed also around the first bottom protection region 15 and the second bottom protection region 16, the n-type impurity concentration around the first bottom protection region 15 and the second bottom protection region 16 has become high. That is, in the pn junction including the first bottom protection region 15 and the first low-resistance region 33 and the pn junction including the second bottom protection region 16 and the second low-resistance region 34, the potential of the n-type region of the pn junction increases more than that in the case of including the drift layer 2. As the potential of the n-type region of the pn junction increases, the built-in voltage of the body diode including the pn junction also increases, and therefore current becomes less likely to flow through the body diode.

Here, when the body diode including the pn junction is made of silicon carbide (SiC), current normally flows through the body diode at about 3.5 V from a band gap of silicon carbide. However, in a case where the potential of the n-type region of the pn junction portion is high, the body diode is not turned on unless an accordingly higher bias is applied. Therefore, when the body diode is applied with a forward bias, bipolar operation becomes suppressed up to a higher voltage at the pn junction of the first bottom protection region 15 and the second bottom protection region 16 adjacent to the first low-resistance region 33 and the second low-resistance region 34.

On the other hand, the SBD can be turned on by applying a bias by a Schottky barrier, and is normally turned on at a voltage lower than that of the body diode including the pn junction, such as about 1 to 2 V. Therefore, when a forward bias is applied, a Schottky current that is a unipolar current due to the SBD first starts to flow, and when the bias becomes higher, a bipolar current due to the body diode starts to flow.

Therefore, by forming the first low-resistance region 33 and the second low-resistance region 34 having an n-type impurity concentration higher than that of the drift layer 2 around the first bottom protection region 15 and the second bottom protection region 16, it is possible to increase the potential of the n-type region of the pn junction and increase the operating voltage at the body diode including the pn junction, and therefore it is possible to achieve a higher maximum unipolar current in the SBD.

Next, modifications of the semiconductor device 301 according to the third embodiment will be described. In the semiconductor device 302 according to the first modification, a portion of the drift layer 2 positioned above the lower portions of the first bottom protection region 15 and the second bottom protection region 16 is formed as a low-resistance region 35. The low-resistance region 35 is an n-type semiconductor region formed on the first drift layer 25 and having an n-type impurity concentration higher than that of the first drift layer 25.

In the low-resistance region 35, a portion formed in the MOS region 19 (a region between the first connection regions 17 adjacent in the extension direction of the gate trench 6) corresponds to the first low-resistance region 33, and a portion formed in the SBD region 20 (a region between the second connection regions 18 adjacent in the extension direction of the Schottky trench 10) corresponds to the second low-resistance region 34. Other configurations are similar to those of the semiconductor device 301 shown in FIG. 21 and the like.

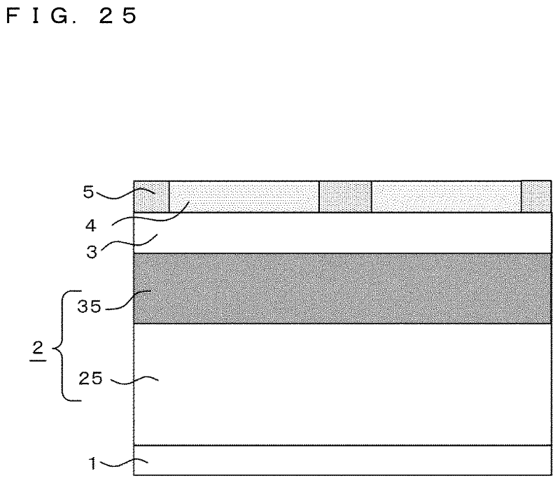

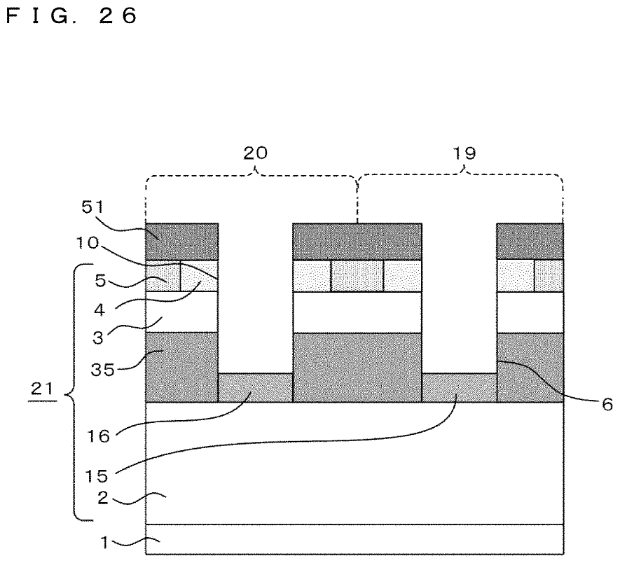

Next, a method for producing the semiconductor device 302 according to the first modification will be described. FIGS. 25 and 26 are views showing some processes of the method for producing the semiconductor device 302 according to the first modification. In the semiconductor device 302, the low-resistance region 35 can be formed similarly to the method for producing shown in FIG. 5 of the first embodiment. That is, as shown in FIG. 25, after the n-type first drift layer 25 is formed on the substrate 1 by epitaxial growth, the n-type low-resistance region 35 is formed on the first drift layer 25 by epitaxial growth. The combination of the first drift layer 25 and the low-resistance region 35 corresponds to the drift layer 2 described above.

Subsequently, the body region 3, the source region 4, and the body contact region 5 are formed similarly to the method for producing shown in FIG. 3 of the first embodiment.

Then, in FIG. 26, using the first mask 51, the gate trench 6 and the Schottky trench 10 that penetrate the source region 4 and the body region 3 from the surface of the semiconductor layer 21 and reach the low-resistance region 35 are formed by reactive ion etching (RIE). At this time, as shown in FIG. 26, the gate trench 6 and the Schottky trench 10 are formed such that the trench bottom becomes shallower than the lower portions of the first low-resistance region 33 and the second low-resistance region 34. Furthermore, by using the first mask 51, ion implantation is performed in a direction perpendicular to the surface of the semiconductor layer 21 to form the first bottom protection region 15 at the bottom of the gate trench 6 and for the second bottom protection region 16 at the bottom of the Schottky trench 10. At this time, the first bottom protection region 15 and the second bottom protection region 16 are formed such that their lower portions have the depths equal to or a deeper position than the lower portion of the low-resistance region 35. Thereafter, the first connection region 17 and the second connection region 18 are formed similarly to the method for producing shown in FIG. 6.

By doing this, it is possible to form the low-resistance region 35 in a portion of the drift layer 2 positioned above the lower portions of the first bottom protection region 15 and the second bottom protection region 16. Other parts can be produced similarly to the semiconductor device 101 of the first embodiment.

Also in the semiconductor device 302 according to the first modification, effects similar to those described in the first embodiment and the third embodiment can be achieved.

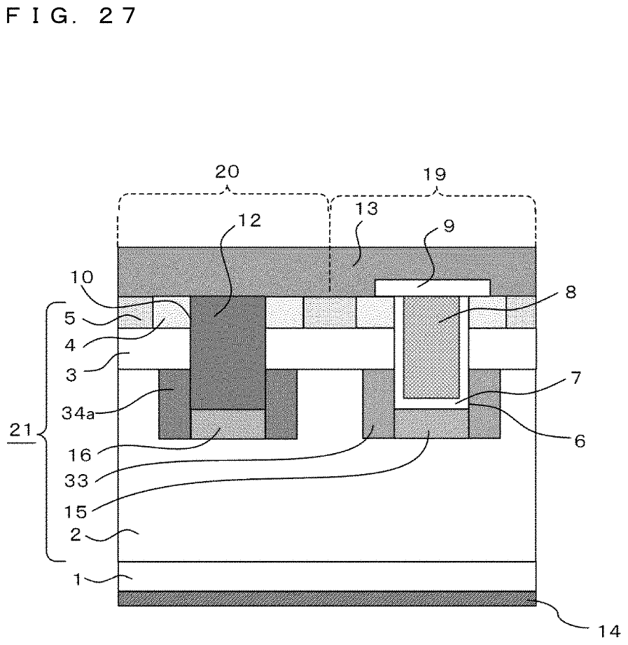

FIG. 27 is a schematic cross sectional view showing a cross section of a part of a cell region in a semiconductor device 303 of the second modification. As shown in FIG. 27, in the semiconductor device 303 according to the second modification, the first low-resistance region 33 is formed in the MOS region 19, and a second low-resistance region 34a is formed in the SBD region 20. The second low-resistance region 34a is formed such that the n-type impurity concentration becomes higher than that of the first low-resistance region 33. Other configurations are similar to those of the semiconductor device 301 shown in FIG. 21 and the like.

Next, a method for producing the semiconductor device 303 will be described. First, similarly to the method for producing the semiconductor device 101 described in the first embodiment, as shown in FIG. 4, after the gate trench 6, the Schottky trench 10, the first bottom protection region 15, and the second bottom protection region 16 are formed. Subsequently, after a mask having an opening only in the MOS region 19 is formed on the semiconductor layer 21, inclined ion implantation is performed from the inner wall of the gate trench 6 to form the first low-resistance region 33. After the mask is removed, a mask having an opening only in the SBD region 20 is formed on the semiconductor layer 21, and oblique ion implantation is performed from the inner wall of the Schottky trench 10 to form the second low-resistance region 34a. Thereafter, the first connection region 17 and the second connection region 18 are formed similarly to the method for producing shown in FIG. 6.

The order of forming the first low-resistance region 33 and the second low-resistance region 34a may be reversed, or they may be formed similarly to the method for producing shown in FIG. 23.

Also in the semiconductor device 303 according to the second modification, effects similar to those described in the first embodiment and the third embodiment can be achieved.

As described above, when the width of the Schottky trench 10 becomes equal to or greater than the width of the gate trench 6, or when the depth of the Schottky trench 10 becomes equal to or less than the depth of the gate trench 6, the electric field applied to the second bottom protection region 16 and the second connection region 18 is equal to or further reduced. In this case, by making the second interval dp2 between the second connection regions 18 smaller than the first interval dp1 between the first connection regions 17, it is possible to reduce the electric field strength of the Schottky interface 22, and at the same time, it is possible to relax the electric field applied to the pn junction at the end portion of the second connection region 18 more than the electric field applied to the pn junction at the end portion of the first connection region 17. Therefore, the impurity concentration of the second low-resistance region 34 in the SBD region 20 can be increased by the lower maximum electric field strength at the end portion of the second connection region 18.

The semiconductor device 303 according to the second modification can reduce the resistance of the SBD region 20 by increasing the impurity concentration of the second low-resistance region 34a and can obtain a higher Schottky current while avoiding deterioration in the withstand voltage at the element and an increase in the leakage current due to an increase in the electric field strength applied to the end portion of the second connection region 18.

### Fourth Embodiment

In the present embodiment, the semiconductor device according to any of the first to third embodiments described above is applied to a power conversion apparatus. Although the present disclosure is not limited to a specific power conversion apparatus, a case where the present disclosure is applied to a three-phase inverter will be described below as the fourth embodiment.

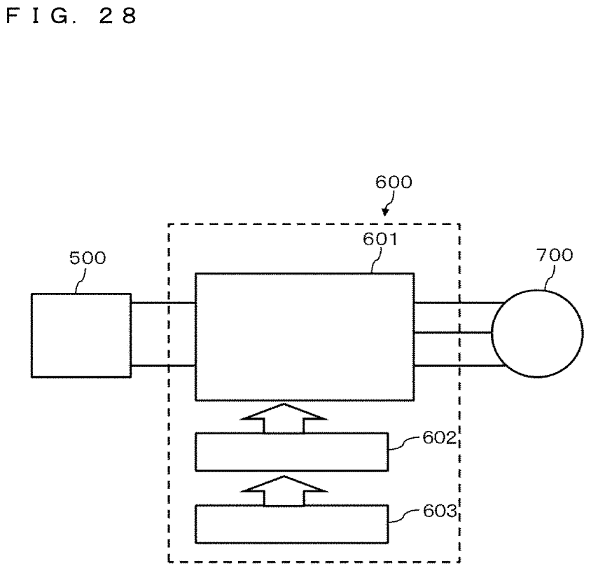

FIG. 28 is a block diagram showing the configuration of a power conversion system applied with the power conversion apparatus according to the present embodiment.

The power conversion system shown in FIG. 28 includes a power source 500, a power conversion apparatus 600, and a load 700. The power source 500 is a direct-current power source, and supplies direct-current power to the power conversion apparatus 600. The power source 500 can include various components, and can include, for example, a direct-current system, a solar battery, and a storage battery, or may include a rectifier circuit or an AC/DC converter connected to an alternating-current system. The power source 500 may include a DC/DC converter that converts direct-current power output from a direct-current system into predetermined power.

The power conversion apparatus 600 is a three-phase inverter connected between the power source 500 and the load 700, converts direct-current power supplied from the power source 500 into alternating-current power, and supplies the alternating-current power to the load 700. As shown in FIG. 28, the power conversion apparatus 600 includes a main conversion circuit 601 that converts input direct-current power into alternating-current power and outputs the alternating-current power, a drive circuit 602 that outputs a drive signal for driving each switching element of the main conversion circuit 601, and a control circuit 603 that outputs, to the drive circuit 602, a control signal for controlling the drive circuit 602.

The load 700 is a three-phase electric motor driven by the alternating-current power supplied from the power conversion apparatus 600. The load 700 is not limited to a specific application but is an electric motor mounted on various electric equipment, and is used as, for example, an electric motor for a hybrid vehicle, an electric vehicle, a railway vehicle, an elevator, or an air conditioner.

Hereinafter, details of the power conversion apparatus 600 will be described. The main conversion circuit 601 includes a switching element and a freewheeling diode (not illustrated), converts direct-current power supplied from the power source 500 into alternating-current power by switching of the switching element, and supplies the alternating-current power to the load 700. Although there are various specific circuit configurations of the main conversion circuit 601, the main conversion circuit 601 according to the present embodiment is a two-level three-phase full-bridge circuit, and can include six switching elements and six freewheeling diodes connected in an antiparallel manner to the respective switching elements. The semiconductor device according to any of the above-described first to third embodiments is applied to at least any of the switching elements and the freewheeling diodes of the main conversion circuit 601. Among them, the MOSFET structure arranged in the MOS region 19 can be used as a switching element, and the SBD arranged in the SBD region 20 can be used as a freewheeling diode. The six switching elements are connected in series for every two switching elements to constitute upper and lower arms, and each of the upper and lower arms constitutes each phase (U-phase, V-phase, W-phase) of the full-bridge circuit. Then, an output terminal of each of the upper and lower arms, that is, three output terminals of the main conversion circuit 601 are connected to the load 700.

The semiconductor devices according to the first to third embodiments have an integrated structure in which the switching element and the freewheeling diode are built in one chip. Therefore, by using the MOSFET structure arranged in the MOS region 19 as the switching element of the main conversion circuit 601 and using the SBD arranged in the SBD region 20 as the freewheeling diode, it is possible to reduce the mounting area as compared with use of two or more different chips in which the switching element and the freewheeling diode are separately formed.

The drive circuit 602 generates a drive signal for driving the switching element of the main conversion circuit 601, and supplies the drive signal to a gate electrode of the switching element of the main conversion circuit 601. Specifically, in accordance with a control signal from the control circuit 603 described later, a drive signal for bringing the switching element into an on state and a drive signal for bringing the switching element into an off state are output to the gate electrode of the respective switching elements. When the switching element is maintained in the on state, the drive signal is a voltage signal (on signal) equal to or greater than a threshold voltage of the switching element, and when the switching element is maintained in the off state, the drive signal becomes a voltage signal (off signal) equal to or less than the threshold voltage of the switching element.

The control circuit 603 controls the switching elements of the main conversion circuit 601 so that desired power is supplied to the load 700. Specifically, a time (on time) at which each switching element of the main conversion circuit 601 is to be brought into the on state is calculated based on the power to be supplied to the load 700. For example, it is possible to control the main conversion circuit 601 by PWM control that modulates the on time of the switching element according to the voltage to be output. Then, a control command (control signal) is output to the drive circuit 602 so that an on signal is output to the switching element to be brought into the on state at each time point, and an off signal is output to the switching element to be brought into the off state at each time point. The drive circuit 602 outputs, as a drive signal, an on signal or an off signal to the gate electrode of each switching element according to this control signal.

In the power conversion apparatus according to the present embodiment, since the semiconductor device according to any of the first to third embodiments is applied as the switching element of the main conversion circuit 601, reliability improvement in the power conversion apparatus can be achieved by use of a highly reliable semiconductor device in which a decrease in capacitance and bipolar deterioration are suppressed.

In the present embodiment, an example in which the present disclosure is applied to a two-level three-phase inverter has been described, but the present disclosure is not limited to this, and can be applied to various power conversion apparatuses. In the present embodiment, the two-level power conversion apparatus is assumed, but a three-level or multi-level power conversion apparatus may be assumed, or the present disclosure may be applied to a single-phase inverter in a case where power is supplied to a single-phase load. In a case of supplying power to a direct-current load or the like, it is also possible to apply the present disclosure to a DC/DC converter or an AC/DC converter.

The power conversion apparatus applied with the present disclosure is not limited to the case where the above-described load is an electric motor, and for example, the power conversion apparatus can be used as a power source apparatus for an electric discharge machine, a laser beam machine, an induction heating cooker, or a noncontact power supply system, and can also be used as a power conditioner for a photovoltaic system, a power storage system, or the like.

### CONCLUSIONS

In the first to third embodiments according to the present disclosure described above, the case where the semiconductor material is silicon carbide has been described, but other semiconductor materials may be used. That is, the substrate 1 and the semiconductor layer 21 including the drift layer 2, the body region 3, the source region 4, and the body contact region 5 can be made of other semiconductor materials. Examples of other semiconductor materials include a so-called wide band gap semiconductor having a wider band gap than that of silicon. Examples of the wide band gap semiconductors other than silicon carbide include gallium nitride, aluminum nitride, aluminum gallium nitride, gallium oxide, and diamond. Also when these wide band gap semiconductors are used, a similar effect can be achieved.

In each of the above-described embodiments described in the present description, a material, a dimension, a shape, a relative arrangement relationship, a condition for carrying out, or the like of each constituent element may be described, but these are examples in all aspects, and each of the embodiments is not limited to those described. Therefore, numerous modifications not exemplified are assumed within the scope of each of the embodiments. The numerous modifications include, for example, a case of modifying any constituent element, a case of adding any constituent element, or a case of omitting any constituent element, and a case of extracting at least one constituent element in at least one embodiment and combining it with a constituent element in another embodiment.

As long as no contradiction arises, as for “one” constituent element described as such in each of the above embodiments, “one or more” of them may be provided. Furthermore, each constituent element is a conceptual unit, and includes a case where one constituent element includes a plurality of structures and a case where one constituent element corresponds to a part of a certain structure.

None of the descriptions in the present description is recognized as being related art.

The embodiments can be freely combined, and the embodiments can be appropriately modified or omitted.

### EXPLANATION OF REFERENCE SIGNS

1 substrate, 2 drift layer, 3 body region, 4 source region, 5 body contact region, 6 gate trench, 7 gate insulating film, 8 gate electrode, 9 interlayer insulating film, 10 Schottky trench, 11 contact region, 12 Schottky electrode, 13 source electrode, 14 drain electrode, 15 first bottom protection region, 16 second bottom protection region, 17 first connection region, 18, 18a, 18b second connection region, 19 MOS region, 20 SBD region, 21 semiconductor layer, 22 Schottky interface, 25 first drift layer, 26 second drift layer, 31, 31a, 31b first electric field relaxation region, 32, 32a, 32b second electric field relaxation region, 33 first low-resistance region, 34, 34a second low-resistance region, 35 low-resistance region, 51 first mask, 52 second mask, 53 third mask, 54 fourth mask, 55 fifth mask, 101, 102, 103, 201, 202, 203, 301, 302, 303 semiconductor device, 500 power source, 600 power conversion apparatus, 601 main conversion circuit, 602 drive circuit, 603 control circuit, 700 load

1. A semiconductor device comprising:
a drift layer of a first conductivity type;
a body region of a second conductivity type;
a source region of a first conductivity type;
a gate insulating film provided in a gate trench penetrating the body region in a thickness direction of the drift layer;
a gate electrode provided in the gate trench and provided to oppose the source region via the gate insulating film;
a first bottom protection region of a second conductivity type provided below the gate insulating film;
a plurality of first connection regions of a second conductivity type provided at a first interval in an extension direction of the gate trench and electrically connecting the first bottom protection region and the body region;
a Schottky electrode provided in a Schottky trench penetrating the body region in the thickness direction of the drift layer, the Schottky electrode having a Schottky interface formed on a side surface of the Schottky trench;
a second bottom protection region of a second conductivity type provided below the Schottky electrode; and
a plurality of second connection regions of a second conductivity type provided at a second interval smaller than the first interval in an extension direction of the Schottky trench and electrically connecting the second bottom protection region and the body region.

2. The semiconductor device according to claim 1, wherein
the first connection regions are provided on both side surfaces of the gate trench.

3. The semiconductor device according to claim 1, wherein
the second connection regions are provided on both side surfaces of the Schottky trench.

4. The semiconductor device according to claim 1, wherein
a length of each of the second connection regions in the extension direction of the Schottky trench is longer than a length of each of the first connection regions in the extension direction of the gate trench.

5. The semiconductor device according to claim 1, wherein
the second connection regions are higher than the first connection regions in impurity concentration of the second conductivity type.

6. The semiconductor device according to claim 1, further comprising a first electric field relaxation region of a second conductivity type provided below the first connection regions and lower than the first connection regions in impurity concentration of the second conductivity type.

7. The semiconductor device according to claim 6, wherein
the first electric field relaxation region is provided below the first bottom protection region.

8. The semiconductor device according to claim 1, further comprising a second electric field relaxation region of a second conductivity type provided below the second connection regions and lower than the second connection regions in impurity concentration of the second conductivity type.

9. The semiconductor device according to claim 8, wherein
the second electric field relaxation region is provided below the second bottom protection region.

10. The semiconductor device according to claim 1, further comprising a first low-resistance region provided between the first connection regions in the extension direction of the gate trench, the first low-resistance region higher than the drift layer in impurity concentration of the first conductivity type.

11. The semiconductor device according to claim 1, further comprising a second low-resistance region provided between the second connection regions in the extension direction of the Schottky trench, the second low-resistance region higher than the drift layer in impurity concentration of the first conductivity type.

12. The semiconductor device according to claim 11, further comprising a first low-resistance region provided between the first connection regions in the extension direction of the gate trench, the first low-resistance region higher than the drift layer in impurity concentration of the first conductivity type, wherein
the second low-resistance region is higher than the first low-resistance region in impurity concentration of the first conductivity type.

13. The semiconductor device according to claim 1, wherein
a wide band gap semiconductor is used as a semiconductor material for the drift layer.

14. The semiconductor device according to claim 1, wherein
the drift layer has a main surface provided with an off angle larger than 0° in an <11-20> direction, and silicon carbide is used as a semiconductor material, and
the gate trench and the Schottky trench are provided in parallel to the <11-20> direction.

15. The semiconductor device according to claim 1, wherein
the gate trench and the Schottky trench have depths equal to each other in the thickness direction of the drift layer.

16. A power conversion apparatus comprising:
a main conversion circuit that has the semiconductor device according to claim 1 and converts and outputs power to be input;
a drive circuit that outputs, to the semiconductor device, a drive signal for driving the semiconductor device; and
a control circuit that outputs, to the drive circuit, a control signal for controlling the drive circuit.

17. A method for producing a semiconductor device, the method comprising:
a step of forming a body region of a second conductivity type in an upper layer portion of a drift layer of a first conductivity type;
a step of selectively forming a source region of a first conductivity type in an upper layer portion of the body region;
a step of forming a gate trench penetrating the source region and the body region and reaching the drift layer;
a step of forming a Schottky trench penetrating the body region and reaching the drift layer;
a step of forming a first bottom protection region of a second conductivity type below the gate trench;
a step of forming a second bottom protection region of a second conductivity type below the Schottky trench;
a step of forming a plurality of first connection regions of a second conductivity type so as to connect the body region and the first bottom protection region by performing ion implantation in an oblique direction with respect to a side surface of the gate trench using a mask periodically opened at a first interval in an extension direction of the gate trench;
a step of forming a plurality of second connection regions of a second conductivity type so as to connect the body region and the second bottom protection region by performing ion implantation in an oblique direction with respect to a side surface of the Schottky trench using a mask periodically opened at a second interval smaller than the first interval in an extension direction of the Schottky trench;
a step of forming a gate insulating film on a bottom and a side surface of the gate trench;
a step of forming a gate electrode so as to embed the gate trench via the gate insulating film; and
a step of forming a Schottky electrode in the Schottky trench.

18. A method for producing a semiconductor device, the method comprising:
a step of selectively forming, by ion implantation, a first bottom protection region of a second conductivity type and a second bottom protection region of a second conductivity type in an upper layer portion of a first drift layer of a first conductivity type;
a step of forming, by epitaxial growth, a second drift layer of a first conductivity type on the first drift layer, the first bottom protection region, and the second bottom protection region;
a step of forming a body region of a second conductivity type in an upper layer portion of the second drift layer;
a step of selectively forming a source region of a first conductivity type in an upper layer portion of the body region;
a step of forming a gate trench penetrating the source region and the body region and reaching the first bottom protection region;
a step of forming a Schottky trench penetrating the body region and reaching the second bottom protection region;
a step of forming a plurality of first connection regions of a second conductivity type so as to connect the body region and the first bottom protection region by performing ion implantation in an oblique direction with respect to a side surface of the gate trench using a mask periodically opened at a first interval in an extension direction of the gate trench;
a step of forming a plurality of second connection regions of a second conductivity type so as to connect the body region and the second bottom protection region by performing ion implantation in an oblique direction with respect to a side surface of the Schottky trench using a mask periodically opened at a second interval smaller than the first interval in an extension direction of the Schottky trench;
a step of forming a gate insulating film on a bottom and the side surface of the gate trench;
a step of forming a gate electrode so as to embed the gate trench via the gate insulating film; and
a step of forming a Schottky electrode in the Schottky trench.

19. The method for producing a semiconductor device according to claim 18, further comprising a step of selectively forming, by ion implantation, a first electric field relaxation region and a second electric field relaxation region of a second conductivity type in the upper layer portion of the first drift layer before the step of forming the first bottom protection region and the second bottom protection region, wherein
the first bottom protection region is formed to be in contact with the first electric field relaxation region, and the second bottom protection region is formed to be in contact with the second electric field relaxation region.
